(19) United States
(12) Patent Application Publication
(10) Pub. No.: US 2026/0155159 A1
(43) Pub. Date: Jun. 4, 2026

(54) SEMICONDUCTOR DEVICES AND DATA STORAGE SYSTEMS INCLUDING THE SAME

(71) Applicant: SAMSUNG ELECTRONICS CO., LTD., Suwon-si (KR)

(72) Inventors: Joonsung KIM, Suwon-si (KR); Sukkang SUNG, Suwon-si (KR)

(73) Assignee: SAMSUNG ELECTRONICS CO., LTD., Suwon-si (KR)

(21) Appl. No.: 19/229,089

(22) Filed: Jun. 5, 2025

(30) Foreign Application Priority Data
Dec. 4, 2024 (KR) 10-2024-0178211

(51) Int. Cl. G11C 5/06; G11C 16/04; G11C 16/08; H01L 23/00; H01L 25/18; H10B 41/10; H10B 41/27; H10B 41/35; H10B 41/41; H10B 43/10; H10B 43/27; H10B 43/35; H10B 43/40; H10B 80/00; H10D 80/30

(52) U.S. Cl. CPC G11C 5/063; G11C 16/0483; G11C 16/08; H10B 41/10; H10B 41/27; H10B 41/35; H10B 41/41; H10B 43/10; H10B 43/27; H10B 43/35; H10B 43/40; H10B 80/00; H10D 80/30; H10W 90/00; H10W 90/792

(57) ABSTRACT

A semiconductor device includes a first memory structure, a second memory structure disposed on the first memory structure, and a peripheral circuit structure disposed adjacent to a lower portion of the first memory structure. The first memory structure includes a first stack structure including first gate electrodes stacked in a vertical direction, first channel structures penetrating the first stack structure in the vertical direction, first circuit interconnections connected to the first channel structures, and a first bonding structure connected to the first circuit interconnections. The second memory structure includes second stack structures including second gate electrodes stacked in the vertical direction, second channel structures penetrating the second stack structures in the vertical direction, second circuit interconnections connected to the second channel structures, and a second bonding structure connected to the second circuit interconnections and bonded to the first bonding structure. the first and second channel structures differ in type.

### CROSS-REFERENCE TO RELATED APPLICATION(S)

This application claims benefit of priority to Korean Patent Application No. 10-2024-0178211 filed on Dec. 4, 2024 in the Korean Intellectual Property Office, the disclosure of which is incorporated herein by reference in its entirety.

### BACKGROUND

Example embodiments of the present disclosure relate to a semiconductor device and a data storage system including the same.

A semiconductor device able to store high-capacity data in a data storage system requiring data storage has been required. Accordingly, a method for increasing data storage capacity of a semiconductor device has been researched. For example, as a method for increasing data storage capacity of a semiconductor device, a semiconductor device including memory cells disposed three-dimensionally, instead of memory cells disposed two-dimensionally, has been suggested.

### SUMMARY

An example embodiment of the present disclosure provides a semiconductor device having improved integration density and reliability.

An example embodiment of the present disclosure provides a data storage system including a semiconductor device having improved integration density and reliability.

According to an example embodiment of the present disclosure, a semiconductor device includes a first memory structure including a first stack structure including first gate electrodes stacked and spaced apart from each other in a vertical direction, first channel structures penetrating the first stack structure in the vertical direction, first circuit interconnections connected to the first channel structures, and a first bonding structure connected to the first circuit interconnections; a second memory structure disposed on the first memory structure, and including second stack structures including second gate electrodes stacked and spaced apart from each other in the vertical direction, second channel structures penetrating the second stack structures in the vertical direction, second circuit interconnections connected to the second channel structures, and a second bonding structure connected to the second circuit interconnections and bonded to the first bonding structure; and a peripheral circuit structure disposed in a lower portion of the first memory structure and electrically connected to the first memory structure by a third bonding structure, wherein a type of the first channel structures is different from a type of the second channel structures.

According to an example embodiment of the present disclosure, a semiconductor device includes a peripheral circuit structure including a first page buffer and a second page buffer, a first row decoder and a second row decoder, and a logic controller selectively operating the first page buffer and the first row decoder or the second page buffer and the second row decoder depending on characteristics of data to be stored; a first memory structure disposed on the peripheral circuit structure, and including a first stack structure including first gate electrodes stacked and spaced apart from each other in a vertical direction and each receiving a first word signal from the first row decoder, first channel structures penetrating the first stack structure in the vertical direction, and first bitlines connected to the first channel structures and receiving first bit signals from the first page buffer; and a second memory structure disposed on the first memory structure, and including second stack structures including second gate electrodes stacked and spaced apart from each other in the vertical direction and each receiving a second word signal from the second row decoder, second channel structures penetrating the second stack structures in the vertical direction, and second bitlines connected to the second channel structures and receiving second bit signals from the second page buffer, wherein the first channel structures store hot data, and the second channel structures store cold data.

According to an example embodiment of the present disclosure, a data storage system includes a main substrate; a semiconductor device on the main substrate; and a controller electrically connected to the semiconductor device on the main substrate, wherein the semiconductor device includes a first memory structure including a first stack structure including first gate electrodes stacked and spaced apart from each other in the vertical direction, first channel structures penetrating the first stack structure in the vertical direction, first circuit interconnections connected to the first channel structures, and a first bonding structure connected to the first circuit interconnections; a second memory structure disposed on the first memory structure, and including second stack structures including second gate electrodes stacked and spaced apart from each other in the vertical direction, second channel structures penetrating the second stack structures in the vertical direction, second circuit interconnections connected to the second channel structures, and a second bonding structure connected to the second circuit interconnections and bonded to the first bonding structure; and a peripheral circuit structure disposed in a lower portion of the first memory structure and electrically connected to the first memory structure by a third bonding structure, wherein a type of the first channel structures is different from a type of the second channel structures.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan diagram illustrating a semiconductor device according to an example embodiment of the present disclosure;

FIG. 2 is a cross-sectional diagram illustrating a semiconductor device according to an example embodiment of the present disclosure;

FIGS. 3A and 3B are diagrams illustrating the semiconductor device illustrated in FIG. 2, viewed in the Z-direction taken along line I-I′ and line II-II′ respectively;

FIGS. 4A and 4B are enlarged diagrams illustrating a portion of a semiconductor device according to example embodiments of the present disclosure;

FIG. 5 is an enlarged diagram illustrating a portion of the semiconductor device illustrated in FIG. 2 according to example embodiments of the present disclosure;

FIGS. 6 to 8 are cross-sectional diagrams illustrating a semiconductor device according to example embodiments of the present disclosure;

FIG. 9 is a diagram illustrating a data storage system including a semiconductor device according to example embodiments of the present disclosure;

FIG. 10 is a cross-sectional diagram illustrating the semiconductor device illustrated in FIG. 9;

FIGS. 11A to 11F are cross-sectional diagrams illustrating a method of manufacturing a semiconductor device according to example embodiments of the present disclosure;

FIG. 12 is a diagram illustrating a semiconductor device according to example embodiments of the present disclosure; and

FIG. 13 is a perspective diagram illustrating a data storage system including a semiconductor device according to an example embodiment of the present disclosure.

### DETAILED DESCRIPTION

Hereinafter, embodiments of the present disclosure will be described as follows with reference to the accompanying drawings.

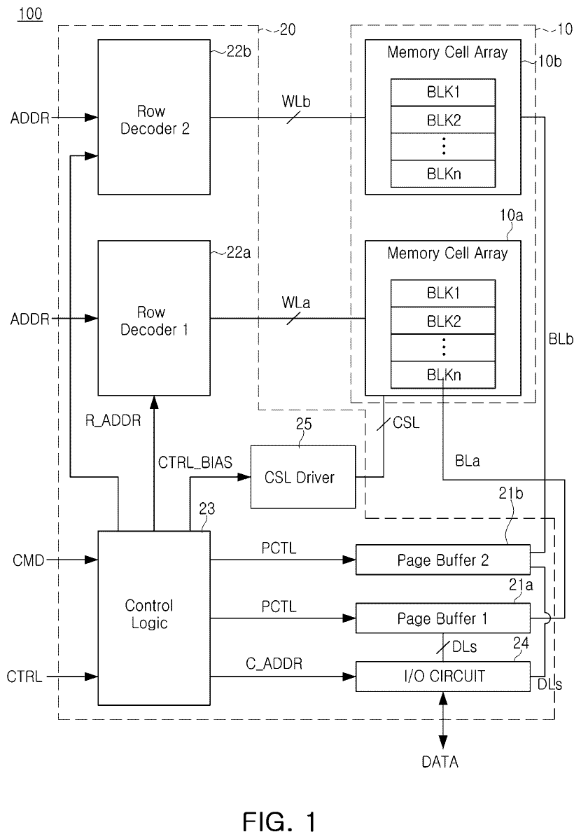

FIG. 1 is a plan diagram illustrating a semiconductor device according to an example embodiment.

Referring to FIG. 1, a semiconductor device 100 may include a memory cell array 10 and a peripheral circuit 20.

The memory cell array 10 may include a first memory cell array 10a and a second memory cell array 10b. The first memory cell array 10a and the second memory cell array 10b may include different memory cells. For example, the first memory cell array 10a and the second memory cell array 10b may include memory cells having different data capacities. For example, the first memory cell array 10a may include first memory cells that store (i)-bit data, and the second memory cell array 10b may include second memory cells that store (j)-bit data. In this case, i and j are natural numbers greater than or equal to 1, and j may be greater than i.

For example, the first memory cell array 10a may include a single level cell (SLC) storing 1-bit data, and the second memory cell array 10b may include a multi-level cell (MLC) and/or a triple level cell (TLC) and/or a quad level cell (QLC).

However, the configuration of the memory cell array 10 is not limited thereto and may be varied. As data capacity stored in one memory cell increases, the data may be stored in the memory cell and a readout operation time may increase.

The peripheral circuit 20 may include first and second page buffers 21a and 21b, first and second row decoders 22a and 22b, a control logic 23, an input/output circuit 24, and a common source line driver 25. Although not illustrated in FIG. 1, the peripheral circuit 20 may further include various circuits, such as a voltage generation circuit (or voltage generator) generating various voltages required for operation of the semiconductor device 100, a circuit for storing data read out from the memory cell array 10, and an input/output interface.

The first memory cell array 10a may be electrically connected to the first page buffer 21a through the first bitline BLa, and may be electrically connected to the first row decoder 22a through the first wordline WLb. Each of the plurality of memory cells included in the plurality of memory cell blocks BLK1, BLK2, . . . , BLKn of the first memory cell array 10a may be configured as a flash memory cell storing 1-bit data. The first memory cell array 10a may include a three-dimensional memory cell array. The three-dimensional memory cell array may include a plurality of NAND strings, and each of the plurality of NAND strings may include a plurality of memory cells connected to a plurality of first wordlines WLa stacked vertically.

The second memory cell array 10b may be electrically connected to the second page buffer 21b through the second bitline BLb and may be electrically connected to the second row decoder 22b through the second wordline WLb. Each of the plurality of memory cells included in the plurality of memory cell blocks BLK1, BLK2, . . . , BLKn of the second memory cell array 10b may be configured as a flash memory cell storing 4 bits of data. The second memory cell array 10b may include a three-dimensional memory cell array. The three-dimensional memory cell array may include a plurality of NAND strings, and each of the plurality of NAND strings may include a plurality of memory cells connected to the plurality of second wordlines WLb stacked vertically.

The peripheral circuit 20 may receive an address ADDR, command CMD, and control signal CTRL from an external entity present externally of the semiconductor device 100, and may transmit data DATA to and receive the data DATA from an external device present externally of the semiconductor device 100.

The first page buffer 21a may be electrically connected to the first memory cell array 10a through the first bitline BLa. The first page buffer 21a may operate as a write driver during a program operation and may apply a voltage according to data DATA to be stored in the first memory cell array 10a to the first bitline BLa, and may operate as a sense amplifier during a read out operation and may sense the data DATA stored in the first memory cell array 10a. The first page buffer 21a may operate in response to the control signal CTRL provided from the control logic 23.

The first row decoder 22a may select at least one of the plurality of cell blocks BLK1, BLK2, . . . BLKn of the first memory cell array 10a in response to an address ADDR from an external entity, and may select the first wordline WLa of the selected memory cell block. The first row decoder 22a may transfer a voltage for performing a memory operation on the first wordline WLa of the selected memory cell block.

The second page buffer 21b may be electrically connected to the second memory cell array 10b through the second bitline BLb. The second page buffer 21b may operate as a write driver during a program operation and may apply a voltage according to the data DATA to be stored in the second memory cell array 10b to the second bitline BLb, and may operate as a sense amplifier during a read out operation and may sense the data DATA stored in the second memory cell array 10b. The second page buffer 21b may be operated in response to the control signal CTRL provided from control logic 23.

The second row decoder 22b may select at least one of the plurality of cell blocks BLK1, BLK2, . . . , BLKn of the second memory cell array 10b in response to an address ADDR from an external entity, and may select a second wordline WLb of the selected memory cell block. The second row decoder 22b may transfer a voltage for performing a memory operation on the second wordline WLb of the selected memory cell block.

The input/output circuit 24 may be connected to the first and second page buffers 21a and 21b through a plurality of data interconnections DLs. The input/output circuit 24 may receive data DATA from the memory controller (illustrated) during a program operation, and may provide program data DATA to the first and second page buffers 21a and 21b based on the column address C_ADDR provided from the control logic 23. The input/output circuit 24 may provide the read out data DATA stored in the first and second page buffers 21a and 21b to the memory controller based on the column address C_ADDR provided from the control logic 23 during a read out operation.

The input/output circuit 24 may transfer an input address or command to the control logic 23 or the first and second row decoders 22a and 22b. The peripheral circuit 20 may further include an electrostatic discharge (ESD) circuit and a pull-up/pull-down circuit.

The control logic 23 may receive the command CMD and the control signal CTRL from the memory controller. In the control logic 23, in response to the command and control signal, hot data, that is, actively accessed data or pieces of cache data, may provide a row address R_ADDR to the first row decoder 22a and a column address C_ADDR to the input/output circuit 24. In the control logic 23, in response to the command and control signal, pieces of long-term storage data, which are cold data, that is, pieces of inactive data not frequently accessed or not accessed at all, may provide a row address R_ADDR to the second row decoder 22b and a column address C_ADDR to the input/output circuit 24.

The control logic 23 may generate various internal control signals used in the semiconductor device 100 in response to the control signal CTRL. For example, the control logic 23 may control voltage levels provided to the first and second wordlines WLa and WLb and the first and second bitlines BLa and BLb when performing a memory operation such as a program operation or an erase operation.

The common source line driver 25 may be electrically connected to the memory cell array 10 through the common source line CSL. The common source line driver 25 may apply a common source voltage (e.g., power voltage) or ground voltage to the common source line CSL based on the control of the control logic 23.

Accordingly, the first memory cell array 10a may function as a high-speed memory storing hot data, and the second memory cell array 10b may function as a main memory which is a low-speed memory storing cold data.

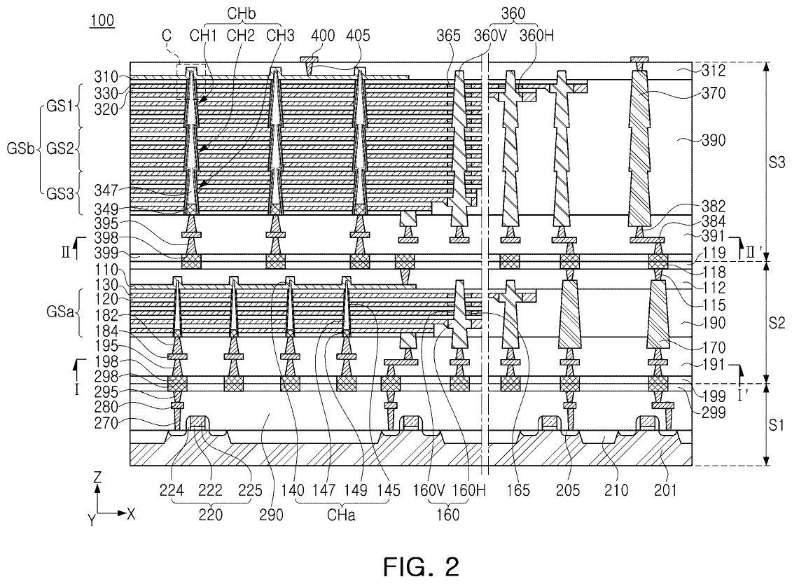

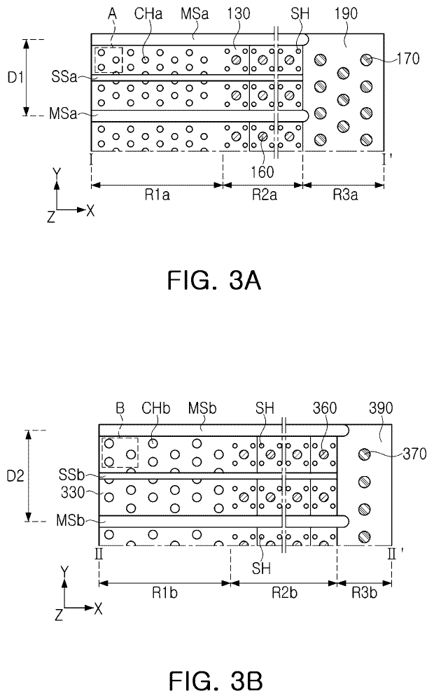

FIG. 2 is a cross-sectional diagram illustrating a semiconductor device according to an example embodiment. FIGS. 3A and 3B are diagrams illustrating the semiconductor device illustrated in FIG. 2, viewed at respective levels. FIG. 3A is a diagram illustrating the semiconductor device in FIG. 2 viewed in the Z-direction (positive direction) taken along line I-I′, and FIG. 3B is a diagram illustrating the semiconductor device in FIG. 2 viewed in the Z-direction (positive direction) taken along line II-II′.

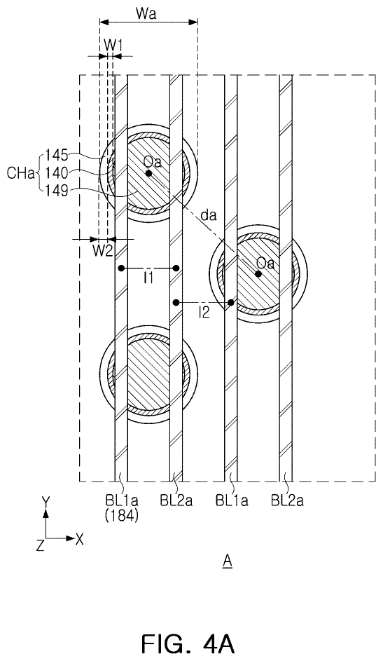

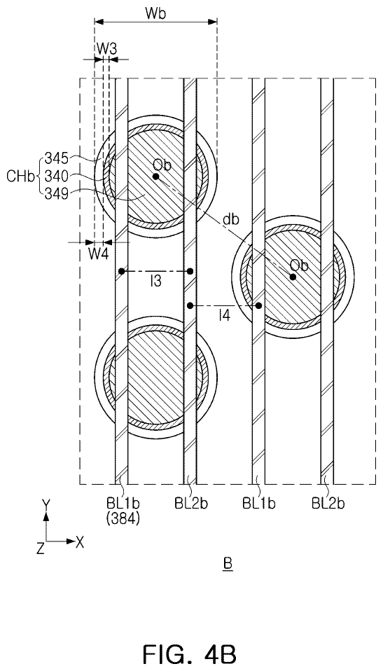

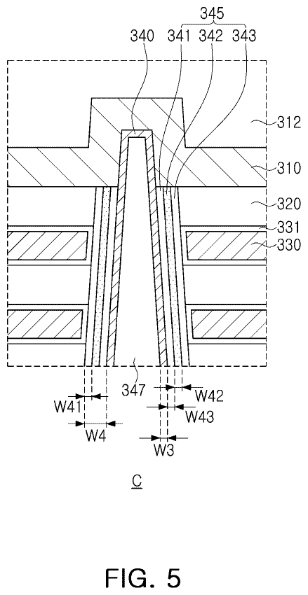

FIGS. 4A and 4B are enlarged diagrams illustrating a portion of a semiconductor device according to example embodiments. FIG. 5 is an enlarged diagram illustrating a portion of the semiconductor device illustrated in FIG. 2 according to example embodiments. FIG. 4A is an enlarged diagram illustrating region “A” in FIG. 3A, FIG. 4B is an enlarged diagram illustrating region “B” in FIG. 3B, and FIG. 5 is an enlarged diagram illustrating region “C” in FIG. 2.

Referring to FIGS. 2 to 5, a semiconductor device 100 may include first to third structures S1, S2, and S3 stacked vertically. For example, the first structure S1 may include a peripheral circuit region PERI of the semiconductor device 100, the second structure S2 may include a first memory cell region of the semiconductor device 100, and the third structure may include a second memory cell region of the semiconductor device. The first structure S1 may correspond to the peripheral circuit 20 in FIG. 1, the second structure S2 may include first channel structures CHa corresponding to the first memory cell array 10a in FIG. 1, and the third structure S3 may include second channel structures CHb corresponding to the second memory cell array 10b in FIG. 1.

A type of the first channel structures CHa may be different from a type of the second channel structures CHb. For example, types of data stored in memory cells in the first channel structures CHa and the second channel structures CHb may be different. For example, the first channel structures CHa may store hot data in each of memory cells, and the second channel structures CHb may store cold data in each of memory cells. Alternatively, the first channel structures CHa and the second channel structures CHb may store different numbers of bits of data in each of memory cells. For example, the first channel structures CHa may store single-bit data in each of memory cells, and the second channel structures CHb may store multi-bit or quad bit data. The first structure S1 may include a substrate 201, source/drain regions 205 and device isolation layers 210 in the substrate 201, circuit devices 220 disposed on the substrate 201, circuit contact plugs 270, circuit interconnection lines 280, a peripheral region insulating layer 290, first bonding vias 295, and first bonding metal layers 298.

The substrate 201 may have an upper surface extending in the X-direction and the Y-direction. The device isolation layers 210 may be formed on the substrate 201 and may define an active region. The source/drain regions 205 including impurities may be disposed in a portion of the active region. The substrate 201 may include a semiconductor material, such as a group IV semiconductor, a group III-V compound semiconductor, or a group II-VI compound semiconductor. For example, the substrate 201 may be provided as a single determinant bulk wafer.

The circuit devices 220 may include a planar transistor. Each of the circuit devices 220 may include a circuit channel dielectric layer 222, spacer layers 224, and a circuit gate electrode 225. The source/drain regions 205 may be disposed in the substrate 201 on both sides of the circuit gate electrode 225.

The peripheral region insulating layer 290 may be disposed on the circuit device 220 on the substrate 201. The circuit contact plugs 270 and the peripheral region insulating layer 290 may be included in a first interconnection structure of a first structure S1. The circuit contact plugs 270 may have a cylindrical shape, may penetrate the peripheral region insulating layer 290 and may be connected to the source/drain regions 205. An electrical signal may be applied to the circuit device 220 by the circuit contact plugs 270. In region not illustrated, the circuit contact plugs 270 may also be connected to the circuit gate electrode 225. The circuit interconnection lines 280 may be connected to the circuit contact plugs 270, may have a line shape, and may be disposed in a plurality of layers. In example embodiments, the number of layers of the circuit contact plugs 270 and the circuit interconnection lines 280 may be varied.

The first bonding vias 295 and the first bonding metal layers 298 may form a first bonding structure and may be disposed on a portion of circuit interconnection lines 280 of the uppermost portion. Upper surfaces of the first bonding metal layers 298 may be exposed to an upper surface of the first structure S1. The first bonding vias 295 and the first bonding metal layers 298 may function as a bonding structure or a bonding layer of the first structure S1 and the second structure S2. Also, the first bonding vias 295 and the first bonding metal layers 298 may provide an electrical connection path to the second structure S2. In example embodiments, a portion of the first bonding metal layers 298 may be disposed only for bonding without being connected to the circuit interconnection lines 280 in a lower portion. The first bonding vias 295 and the first bonding metal layers 298 may include a conductive material, for example, copper (Cu).

In example embodiments, the peripheral region insulating layer 290 may include a bonding insulating layer 299 having a predetermined thickness from an upper surface. The bonding insulating layer 299 may be for dielectric-dielectric bonding with the bonding insulating layer 299 of the second structure S2. The bonding insulating layer 299 may also function as a diffusion barrier for the first bonding metal layers 298, and may include, for example, at least one of SiO, SiN, SiCN, SiOC, SiON, and SiOCN.

The second structure S2 may include a planar conductive layer 110 disposed on the first region R1a, first gate electrodes 130 stacked and spaced apart from each other in the Z-direction on a lower surface of the planar conductive layer 110 and included in the first stack structure GSa, first interlayer insulating layers 120 alternately stacked with the first gate electrodes 130, first channel structures CHa disposed to penetrate the first stack structure GSa in the first region R1a, first isolation regions MSa penetrating the first gate electrodes 130 and extending in one direction, and first lower insulating regions SSa penetrating a portion of the first gate electrodes 130. The second structure S2 may further include a first cell region insulating layer 190 covering the first gate electrodes 130 and a first cover insulating layer 112 on the first planar conductive layer 110. The second structure S2 may further include support structures SH, first contact plugs 160, first through-vias 170, and cell interconnection structures 182 and 184. The second structure S2 may further include a second bonding structure and a third bonding structure, and may further include second bonding vias 195 and second bonding metal layers 198 in a lower portion of the first channel structure CHa as the second bonding structure, and may further include third bonding vias 115 and fourth bonding metal layers 118 in an upper portion of the first channel structure CHa as the third bonding structure.

The second structure S2 is a memory cell region, and may be referred herein as a first memory structure. In the first region R1a, the first gate electrodes 130 are vertically stacked and the first channel structures CHa are disposed, and the memory cells may be disposed in the first region R1a. In the second region R2a, the first gate electrodes 130 may extend with different lengths and may be provided to electrically connect the memory cells to the first structure S1. The second region R2a may be disposed at least in one direction, for example, at least on one end of the first region R1a in the X-direction. In the third region R3a, the first through-vias 170 may be disposed, and may be disposed at one side of the second region R2a, or may also be disposed on one side of the first region R1a. The third region R3a may be an edge region in which the first gate electrode 130 is not disposed, and the cell region insulating layer 190 may be disposed. Alternatively, the first interlayer insulating layer 120 and the sacrificial insulating layer may remain in the third region R3a.

The planar conductive layer 110 may be configured as a conductive plate structure having an upper surface extending in the X-direction and the Y-direction from the first region R1a. The planar conductive layer 110 may have an upper surface extending in the X-direction and the Y-direction. The planar conductive layer 110 may include a metal material, such as tungsten (W), aluminum (Al), or copper (Cu). The planar conductive layer 110 may further include a diffusion barrier on a lower portion. The diffusion barrier may include a metal nitride. For example, the diffusion barrier may include tungsten nitride (WN), tantalum nitride (TaN), titanium nitride (TiN), or a combination thereof.

The planar conductive layer 110 may function as a common source line CSL of the semiconductor device 100. The planar conductive layer 110 may be in direct contact with a channel layer on one end of the first channel structures CHa, and may be physically and electrically connected to the channel layer.

The first cover insulating layer 112 may be disposed while covering the planar conductive layer 110 on at least a portion of the second region R2a. The first cover insulating layer 112 may include silicon oxide, silicon nitride, silicon carbide, or silicon oxynitride.

The first substrate insulating layer 191 may be disposed in a region in which the first channel structures CHa, the lower end of the first contact plugs 160 and the first through-via 170 and the interconnection structures 182 and 184 are disposed in a lower portion of the first stack structure GSa of the second structure S2. The first substrate insulating layer 191 may include an insulating material, for example, silicon oxide, silicon nitride, silicon carbide, or silicon oxynitride.

The first stack structure GSa may include at least one stage of the first stack structure GSa vertically stacked. However, in example embodiments, the first stack structure GSa may include two or more stages of the first stack structure GSa, or the first stack structure GSa may include one end of the first stack structure GSa preferably.

The first gate electrodes 130 may include lower gate electrodes 130L included in string select transistors, memory gate electrodes 130M included in a plurality of memory cells, and upper gate electrodes 130U included in a ground select transistor. The number of memory gate electrodes 130M included in the memory cells may be determined depending on capacity of the semiconductor device 100. One of the upper gate electrodes 130U and the lower gate electrodes 130L may also be referred to as an upper select gate electrode and a lower select gate electrode, respectively. In example embodiments, each of the number of the upper gate electrodes 130U and the number of the lower gate electrodes 130L may be 1 to 4 or more, and the upper gate electrode(s) 130U and the lower gate electrode(s) 130L may have a structure the same as or different from as a structure of the memory gate electrodes 130M. In some example embodiments, the upper gate electrodes 130U and/or at least one lower portion gate electrode 130L may not be provided. A portion of the first gate electrodes 130, for example, the memory gate electrodes 130M adjacent to the upper gate electrode(s) 130U or the lower gate electrode(s) 130L, may be dummy gate electrodes. The terms “upper portion and lower portion” of the first gate electrodes 130 may be defined by the process order and may not necessarily represent actual upper and lower portions.

The first gate electrodes 130 may be vertically stacked and spaced apart from each other on the first region R1a and may extend from the first region R1a to the second region R2a with different lengths and may form step structures of a staircase shape in the gate pad regions. As illustrated in FIG. 2, the first gate electrodes 130 may have a shape removed from the gate pad regions by a predetermined depth from an upper portion. The gate pad regions may be disposed so as not to overlap each other in the Z-direction. In example embodiments, the arrangement shape, arrangement order, and depth of the gate pad regions may be varied. In some example embodiments, the first gate electrodes 130 may not be disposed on the gate pad regions.

The first gate electrodes 130 may form step structures in an asymmetrical shape in the X-direction in each of the gate pad regions. The first step structure may be a staircase structure relatively adjacent to the first region R1a and having a level decreasing in the X-direction, and the second step structure may be a staircase structure relatively far from the first region R1a and having a level increasing in the X-direction. For example, in each of the gate pad regions, a slope of the first step structure may be smaller than a slope of the second step structure in the first region R1a. Alternatively, in some example embodiments, the first and second step structures may have symmetrical shapes. In the first step structure, the first gate electrodes 130 may be connected to the first contact plugs 160, and in the second step structure, the first gate electrodes 130 may form a dummy region or a support structure not connected to the first contact plugs 160. In example embodiments, the specific shape of the step structure, the number of first gate electrodes 130 included in each step structure, or the like, are not limited to the example illustrated in FIG. 2. In some example embodiments, the first gate electrodes 130 may be disposed to have step structures in the Y-direction as well.

As illustrated in FIG. 2, by the first step structure, the first gate electrodes 130 may have contact regions in which the first gate electrode 130 in a lower portion extends longer than the first gate electrode 130 in an upper portion, and upwardly exposed from the first interlayer insulating layers 120, respectively. The first gate electrodes 130 may be connected to the first contact plugs 160 in the contact regions, which are end regions, respectively. The first gate electrodes 130 may have an increased thickness in the contact regions. The first gate electrodes 130 may have a greater thickness in the contact regions than in the regions in which other first gate electrodes 130 are disposed on an upper surface.

The first gate electrodes 130 may include a metal material, for example, tungsten (W). In an example embodiment, the first gate electrodes 130 may include polycrystalline silicon or a metal silicide material. The first gate electrodes 130 may include the same material. In example embodiments, the first gate electrodes 130 may further include a planar blocking layer as a diffusion barrier, for example, the diffusion barrier may include tungsten nitride (WN), tantalum nitride (TaN), titanium nitride (TiN), or a combination thereof.

The first interlayer insulating layers 120 may be disposed between the first gate electrodes 130. Similarly to the first gate electrodes 130, the first interlayer insulating layers 120 may be disposed so as to be spaced apart from each other in a direction perpendicular to a lower surface of the planar conductive layer 110 and to extend in the X-direction. The first interlayer insulating layers 120 may include an insulating material such as silicon oxide or silicon nitride.

Each of the first channel structures CHa may form a memory cell string, and may be spaced apart from each other in rows and columns in a lower portion of the planar conductive layer 110 in the first region R1a. The first channel structures CHa may be disposed so as to form a grid pattern or may be disposed in a zigzag pattern in one direction on a x-y plane. The first channel structures CHa may be disposed such that a spacing distance between the first channel structures CHa, that is, a distance between centers Oa of the first channel structures CHa, may be a first spacing distance da as illustrated in FIGS. 3A and 4A. The first channel structures CHa may have a columnar shape, and widths thereof may increase in a direction away from the planar conductive layer 110 depending on an aspect ratio, and may have inclined side surfaces. In example embodiments, the first channel structures CHa disposed at an end of the first region R1a may have at least a portion of dummy channel structures.

A width of the first channel structures CHa may increase downwardly, that is, in a direction away from the planar conductive layer 110, and side surfaces thereof may have a slope. A lower end of the first channel structures CHa may penetrate the uppermost gate electrode 130U, may protrude downwardly, and may have a channel pad 149 at a lower end, and the channel pad 149 may be connected to the stud 182 in a lower portion and may be connected to the lower interconnections 184. The first channel structures CHa may penetrate the first stack structure GSa of one stage and may have a continuous slope without a bent portion.

Each of the first channel structures CHa may include a channel layer 140 disposed in a channel hole, a channel dielectric layer 145, a channel filling insulating layer 147, and a channel pad 149.

As illustrated in the enlarged diagram in FIG. 4A, the channel layer 140 may have an annular shape surrounding the channel filling insulating layer 147 in an internal portion, or may also have a columnar shape such as a cylindrical shape or a prism shape without the channel filling insulating layer 147 in example embodiments. The channel layer 140 may be connected to the planar conductive layer 110 in an upper portion of the channel hole. The channel layer 140 may include a semiconductor material such as polycrystalline silicon or monocrystalline silicon.

The channel layer 140 may not be doped with conductivity-type impurities, such as P-type or N-type impurities, during a manufacturing process. That is, the channel layer 140 may not be intentionally doped with conductivity-type impurities. The channel layer 140 may be formed on a side surface of the channel hole with a predetermined thickness W3 on a x-y plane perpendicular to the Z-direction, and may extend continuously from an upper end to a lower end of the channel hole. A thickness W1 of the channel layer 140 may be between 5 nm to 10 nm, and for example, may be about 6 nm, but an example embodiment thereof is not limited thereto.

The channel dielectric layer 145 may be disposed between the first gate electrodes 130 and the channel layer 140. The channel dielectric layer 145 may be disposed to cover an internal side surface of a channel hole in which the channel structure CHa is disposed. The channel dielectric layer 145 may include a blocking layer, a charge storage layer, and a tunneling layer stacked in order from the first gate electrodes 130. The semiconductor device 100 may further include a planar blocking layer, and the planar blocking layer may extend in the planar direction along the first gate electrodes 130. In some example embodiments, the planar blocking layer may not be provided.

The blocking layer and the planar blocking layer may include silicon oxide (SiO₂), silicon nitride (Si₃N₄), silicon oxynitride (SiON), a high-κ material, or a combination thereof. The charge storage layer may be a charge trap layer or a floating gate conductive layer. The tunneling layer may tunnel electric charges into the charge storage layer and may include, for example, silicon oxide (SiO₂), silicon nitride (Si₃N₄), silicon oxynitride (SiON), or a combination thereof.

The channel dielectric layer 145 may be formed to have a predetermined thickness W2, which may be greater than the predetermined thickness W1 of the channel layer 140. For example, the thickness W2 of the channel dielectric layer 145 may be between 16 nm to 20 nm, and may have, for example, a thickness of about 18 nm, and the blocking layer, the charge storage layer, and the tunneling layer may have similar thicknesses, but an example embodiment thereof is not limited thereto.

The channel filling insulating layer 147 may be spaced apart from a lower end of the channel hole by a predetermined distance and may fill the channel hole up to an upper end of the channel hole in the channel layer 140. The channel filling insulating layer 147 may include an insulating material, for example, silicon oxide (SiO₂), silicon nitride (Si₃N₄), silicon oxynitride (SiON), or a combination thereof.

A channel pad 149 may be disposed at a lower end of the first channel structure CHa. The channel pad 149 may be connected to the channel layer 140. The channel pad 149 may include a conductive material such as a polycrystalline semiconductor, preferably polysilicon, and may include conductivity-type impurities. For example, when N-type impurities are doped and a common voltage is applied, inversion of the channel layer 140 may be induced depending on a common voltage level.

Referring to FIG. 3A and FIG. 4A, when a lower end of the channel hole has a circular shape, a diameter passing through a center Oa of a circle of the channel hole, that is, a width of the lower end of the first channel structure CHa, may be defined as a first channel width Wa. The first channel width Wa may be smaller than the first spacing distance da, and may be 100 nm to 120 nm, and for example, the first channel width Wa may be around 110 nm. The first spacing distance da may be a distance between adjacent first channel structures CHa, and may be defined as a pitch from the center of one first channel structure CHa to the center of an adjacent first channel structure CHa.

The first isolation regions MSa may penetrate at least a portion of the first gate electrodes 130 and may extend in the X-direction. As illustrated in FIG. 2, the first isolation regions MSa may be disposed in parallel to each other. The first isolation regions MSa may penetrate the first gate electrodes 130 and may be connected to the substrate insulating layer 191 therebelow.

A portion of the first isolation regions MSa may extend as an integrated region along the first region R1a and the second region R2a, and the other portion may extend only to a portion of the second region R2a, or may be disposed intermittently in the first region R1a and the second region R2a. However, in example embodiments, the arrangement and the number, of the first isolation regions MSa are not limited to the example illustrated in FIG. 3A.

An isolation insulating layer may be disposed in each of the first isolation regions MSa. The isolation insulating layer may have a shape of which a width increases toward the substrate insulating layer 191 due to a high aspect ratio. The isolation insulating layer may include an insulating material, for example, silicon oxide, silicon nitride, or silicon oxynitride. The spacing distance in the Y direction between the first isolation regions MSa may be the first isolation spacing distance D1.

The first lower insulating regions SSa may extend in the X-direction between the adjacent first isolation regions MSa as illustrated in FIG. 3A. The first lower insulating regions SSa may have a sloped side surface such that a width thereof increases downwardly in the Z-direction. The first lower insulating regions SSa may have a slope direction the same as the slope direction of the first channel structures CHa. The first lower insulating regions SSa may penetrate at least one upper portion gate electrode 130U among the upper portion gate electrodes 130U between the first channel structures CHa. Accordingly, a width of an upper surface of the first lower insulating regions SSa may be smaller than a width of the lower surface. The first lower insulating regions SSa may divide the upper gate electrode 130U in the Y-direction as illustrated in FIG. 3A.

Each of the first lower insulating regions SSa may include a lower isolation insulating layer. The lower isolation insulating layer may include an insulating material, for example, silicon oxide, silicon nitride, or silicon oxynitride.

The first contact plugs 160 may be connected to contact regions of the first gate electrodes 130 in gate pad regions of the second region R2a. The first contact plugs 160 may penetrate at least a portion of the cell region insulating layers 190 and may be connected to the contact regions, upwardly exposed, of the first gate electrodes 130, respectively. The first contact plugs 160 may penetrate the first gate electrodes 130 and may be connected to the interconnection lines 184 below the contact regions. The first contact plugs 160 may be spaced apart from the first gate electrodes 130 below the contact regions by the first contact insulating layers 165. However, in some example embodiments, the first contact plugs 160 may be disposed so as not to penetrate the first gate electrodes 130, and in this case, the first contact plugs 160 may be connected to the contact regions, upwardly exposed, of the first gate electrodes 130, respectively.

The first contact plugs 160 may have a shape corresponding to the first channel structures CHa, or a shape corresponding to the isolation region MS. Each of the first contact plugs 160 may have an inclined side surface having a width increasing downwardly without a bent portion, and may have a cylindrical shape.

As illustrated in FIG. 2, each of the first contact plugs 160 may have a planar extension shape in the contact region. The first contact plug 160 may include a vertical extension portion 160V extending in the Z-direction and a planar extension portion 160H planarly extending from the vertical extension portion 160V and in contact with the first gate electrode 130. The planar extension portion 160H may be disposed along the periphery of the vertical extension portion 160V and an entire side surface thereof may be surrounded by the first gate electrode 130. A length from the side surface of the vertical extension portion 160V to an end of the planar extension portion 160H may be less than a length from the side surface of the vertical extension portion 160V to external side surfaces of the first contact insulating layers 165. The first contact plugs 160 may be spaced apart from the first gate electrodes 130, that is, the first gate electrodes 130, which are not electrically connected, below the contact regions by the first contact insulating layers 165.

The first contact plugs 160 may include a conductive material, for example, at least one of tungsten (W), copper (Cu), aluminum (Al), and alloys thereof. In some example embodiments, the first contact plugs 160 may include a barrier layer extending along a side surface and a bottom surface, or may have an air gap in an internal portion.

The first contact insulating layers 165 may be disposed so as to surround the side surface of each of the first contact plugs 160 below the contact regions. The first contact insulating layers 165 may be spaced apart from each other in the Z-direction at the periphery of each of the first contact plugs 160. The first contact insulating layers 165 may be disposed at substantially the same level as the first gate electrodes 130, respectively. The first contact insulating layers 165 may include an insulating material, for example, silicon oxide, silicon nitride, or silicon oxynitride.

The support structures SH may be disposed at the peripheral of the first contact plugs 160. As illustrated in FIG. 3B, the support structures SH may be disposed in a circular shape in a plan diagram in the second region R2a, and may be arranged in a regular shape at the peripheral of the first contact plugs 160. For example, four support structures SH may be arranged at the peripheral of one first contact plug 160, but an example embodiment thereof is not limited thereto. The support structures SH may be disposed regularly and continuously even in regions in which the first contact plugs 160 are spaced apart from each other in the X-direction.

The support structures SH may penetrate the first stack structures GSa to have the same shape as that of the first contact plugs 160, and may have a cylindrical shape having an inclined side surface of which a width increases downwardly from the first stack structures GSa. The support structures SH may be formed of an insulating material.

The second structure S2 may further include a first through-via 170 penetrating the substrate insulating layer 191 in the third region R3a and connected to the interconnection structures 182 and 184 in a lower portion. The through-via 170 may penetrate the cell region insulating layer 190 and may have a cylindrical shape of which a width increases downwardly similarly to the first contact plugs 160. The first through-via 170 may include a conductive material, and may include the same material as the first contact plugs 160, but an example embodiment thereof is not limited thereto. The first through-vias 170 may include through-vias for connecting to the first structure S1 by connecting to the second contact plugs 360 in the third structure S3, common voltage through-vias for applying voltage of the corresponding level to the planar conductive layer 110, and input/output through-vias for applying input/output signals, but an example embodiment thereof is not limited thereto.

The first cell region insulating layer 190 may be disposed to cover the substrate insulating layer 191 and each of the gate pad regions. The first cell region insulating layer 190 may be formed of an insulating material and may include a plurality of insulating layers.

The studs 182 may be included in an interconnection structure electrically connected to memory cells in the memory cell region CELL. The studs 182 may be electrically connected to the first channel structures CHa and the first contact plugs 160. The studs 182 may not be disposed on the support structures SH. The studs 182 may have a plug shape, but an example embodiment thereof is not limited thereto, and may have a line shape. In example embodiments, the number of the studs 182 and the number of the interconnection lines 184 included in the interconnection structure may be varied. The studs 182 may include a metal, for example, tungsten (W), copper (Cu), aluminum (Al), or the like.

As illustrated in FIG. 4A, cell interconnection lines 184 may include bitlines BL1a and BL2a of the first region R1a connected to the first channel structures CHa. The bitlines BL1a and BL2a may have a line shape extending in the Y-direction, and two bitlines BL1a and BL2a may extend to an upper surface of the first channel structures CHa. That is, when the two bitlines BL1a and BL2a are spaced apart from each other on an upper end of the first channel structures CHa, the studs 182 may be alternately in contact with one of the bitlines BL1a and BL2a on the first channel structures CHa and may electrically connect one of the two bitlines BL1a and BL2a to one of the first channel structures CHa. A spacing distance between the bitlines BL1a and BL2a disposed in the X-direction may be the first distance I1. In this case, the spacing distance between the bitlines BL1a and BL2a may be defined as the distance between centers of widths of the bitlines. The first distance I1 between two bitlines BL1a and BL2a disposed on the first channel structure CHa may be the same as or smaller than the second distance I2 between two bitlines BL1a and BL2a disposed on the neighboring first channel structure CHa. That is, the spacing distance between the bitlines BL1a and BL2a may be the first distance I1, but an example embodiment thereof is not limited thereto.

The cell interconnection lines 184 may include, for example, tungsten (W), aluminum (Al), copper (Cu), tungsten nitride (WN), tantalum nitride (TaN), titanium nitride (TiN), or a combination thereof.

The second bonding vias 195 of the second bonding structure may be disposed in a lower portion of the cell interconnection lines 184 and may be connected to the cell interconnection lines 184, and the second bonding metal layers 198 of the second bonding structure may be connected to the second bonding vias 195. A lower surface of the second bonding metal layers 198 may be exposed to a lower surface of the second structure S2. The second bonding metal layers 198 may be bonded and connected to the first bonding metal layers 298 of the first structure S1. The second bonding vias 195 and the second bonding metal layers 198 may include a conductive material, for example, copper (Cu).

In example embodiments, the substrate insulating layer 191 may include a bonding insulating layer 199 having a predetermined thickness from a lower surface. In this case, the bonding insulating layer 199 may form dielectric-dielectric bonding with the bonding insulating layer 299 of the first structure S1. The bonding insulating layer 199 may include at least one of, for example, SiO, SiN, SiCN, SiOC, SiON, and SiOCN.

The first and second structures S1, S2 may be bonded to each other by bonding between the first bonding metal layers 298 and the second bonding metal layers 198 and bonding between the bonding insulating layers 199 and 299. The bonding between the first bonding metal layers 298 and the second bonding metal layers 198 may be, for example, copper (Cu)-copper (Cu) bonding, and the bonding between the bonding insulating layers 199 and 299 may be, for example, dielectric-dielectric bonding, such as SiCN-SiCN bonding. The first and second structures S1, S2 may be bonded to each other by hybrid bonding including copper (Cu)-copper (Cu) bonding and dielectric-dielectric bonding.

The third bonding vias 115 of the third bonding structure may be connected to the planar conductive layer 110 and the first through-vias 170, and the third bonding metal layers 118 may be connected to the third bonding vias 115. The third bonding metal layers 118 may have an upper surface exposed to an upper surface of the second structure S2. The third bonding metal layers 118 may be bonded and connected to the fourth bonding metal layers 398 of the third structure S3. The third bonding vias 115 and the third bonding metal layers 118 may include a conductive material, for example, copper (Cu).

In example embodiments, a third bonding insulating layer 119 having a predetermined thickness may be included. In this case, the third bonding insulating layer 119 may form dielectric-dielectric bonding with the fourth bonding insulating layer 399 of the third structure S3. The third bonding insulating layer 119 may include at least one of, for example, SiO, SiN, SiCN, SiOC, SiON, and SiOCN.

The first channel structures CHa of the second structure S2 may store 1-bit of data from the first row decoder 22a and the first page buffer 21a to each of memory cells. Accordingly, the structure may function as a single level cell (SLC). Accordingly, the second structure S2 may function as a memory storing cache data or hot data frequently accessed, and may store hot data allocated with a high response speed. For such a relatively high response speed, the structure may be disposed close to the first structure S1, which is a peripheral structure, and may be directly connected.

The third structure S3 may be disposed on the second structure S2.

The third structure S3 may include a planar conductive layer 310 disposed on the first region R1b, second gate electrodes 330 stacked and spaced apart from each other on a lower surface of the planar conductive layer 310 in the Z-direction and included in the second stack structure GSb, second interlayer insulating layers 320 alternately stacked with the second gate electrodes 330, second isolation regions MSb penetrating the stack structure GSb in the first region R1b, penetrating the second channel structures CHb and the second gate electrodes 330, and extending in one direction, and second lower insulating regions SSb penetrating a portion of the second gate electrodes 330. The third structure S3 may further include a second cell region insulating layer 390 covering the second gate electrodes 330 and a second cover insulating layer 312 on the second planar conductive layer 310. The third structure S3 may further include support structures SH, second contact plugs 360, second through-vias 370, and cell interconnection structures. The third structure S3 may further include a fourth bonding structure, and may further include fourth bonding vias 395 and fourth bonding metal layers 398 in a lower portion of the second channel structure CHb as the fourth bonding structure.

The third structure S3 is a memory cell region, and may be referred herein as a second memory structure. In the first region R1b, the second gate electrodes 330 may be vertically stacked and the second channel structures CHb may be disposed, and memory cells may be disposed in the third structure S3. In the second region R2b, the second gate electrodes 330 may extend to different lengths, and may be provided for electrically connecting the memory cells to the first structure S1. The second region R2b may be disposed at least one end of the first region R1b in at least one direction, for example, the X-direction. In the third region R3b, the second through-vias 370 may be disposed, and the third region R3b may be disposed on one side of the second region R2b, or may also be disposed between the first region R1b and the second region R2b, or may be disposed on one side of the second region R2b. The third region R3b may be configured as an edge region in which the gate electrode 330 is not disposed, and the cell region insulating layer 390 may be disposed. Alternatively, in the third region R3b, the second interlayer insulating layer 320 and the second sacrificial insulating layer may remain.

With respect to the second structure S2, in the third structure S3, an area of the second region R2b may be greater, and an area of the third region R3b may be smaller. Specifically, the third structure S3 may include the second region R2b having a larger area such that more second contact plugs 360 may be disposed in the third structure S3 than in the second structure S2.

Also, the third region R3b of the third structure S3 may have a narrower area such that a smaller number of the through-vias 370 are disposed in the third structure S3 than in the second structure S2. The area of the first region R1b may be substantially the same as that of the first region R1a, but an example embodiment thereof is not limited thereto.

The planar conductive layer 310 may be a conductive plate structure having an upper surface extending in the X-direction and the Y-direction from the first region R1b, and may further include a diffusion barrier in an upper portion. The planar conductive layer 310 may have an upper surface extending in the X-direction and the Y-direction. The planar conductive layer 310 may overlap the first planar conductive layer 110 in the Z-direction, but an example embodiment thereof is not limited thereto, and the planar conductive layer 310 may include different areas. The planar conductive layer 310 may include the same material as the first planar conductive layer 110.

The second cover insulating layer 312 may be disposed in an upper portion of the second region R2b while covering the planar conductive layer 310.

The second substrate insulating layer 391 may be disposed in a region in which the lower ends of the second channel structures CHb, the second contact plugs 360 and the second through-via 370 and interconnection structures are disposed in a lower portion of the second stack structure GSb of the third structure S3.

The second stack structure GSb may include at least two stack structures GS1, GS2 and GS3 vertically stacked. In example embodiments, the second stack structure GSb may include three or more stack structures. The second stack structure GSb may include a greater number of stack structures than the first stack structure GSa and may have a greater length in the Z-direction.

The second gate electrodes 330 may include lower gate electrodes 330L included in string select transistors, memory gate electrodes 330M included in a plurality of memory cells, and upper gate electrodes 330U included in a ground select transistor. The number of second memory gate electrodes 330M included in memory cells may be determined depending on capacity of the semiconductor device 100. One of the upper gate electrodes 330U and the lower gate electrodes 330L may also be referred to as an upper select gate electrode and a lower select gate electrode. In example embodiments, each of the number of the upper gate electrodes 330U and the number of the lower gate electrodes 330L may be from one to four or more, and the upper gate electrodes 330U and the lower gate electrodes 330L may have a structure the same as or different from a structure of the memory gate electrodes 330M. In some example embodiments, the upper gate electrodes 330U and/or at least one lower portion gate electrode 330L may not be provided. A portion of the second gate electrodes 330, for example, memory gate electrodes 330M adjacent to the upper gate electrode(s) 330U or the lower gate electrode(s) 330L, may be dummy gate electrodes.

The second gate electrodes 330 may be vertically stacked and spaced apart from each other on the first region R1b, and may extend from the first region R1b to the second region R2b with different lengths and may form step structures having a staircase shape in the gate pad regions, and the description of the step structure may be the same as that of the second structure S2. Accordingly, the number of layers of the gate electrodes 330 of the third structure S3 may be greater than the number of layers of the gate electrodes 130 of the first structure S1, and may be at least 2 to 3 times the number of layers of the gate electrodes 130 of the first structure S1, but an example embodiment thereof is not limited thereto.

The second interlayer insulating layers 320 may be disposed between the second gate electrodes 330.

Each of the second channel structures CHb may form one memory cell string, and may be spaced apart from each other in rows and columns in a lower portion of the second planar conductive layer 310 in the first region R1b. The second channel structures CHb may be disposed to form a grid pattern or may be disposed in a zigzag pattern in one direction on a x-y plane. The second channel structures CHb may be disposed such that a spacing distance between the second channel structures CHb, that is, a distance between centers Ob of each second channel structure CHb, may be a second spacing distance db as illustrated in FIGS. 3B and 4B. The second spacing distance db may be greater than the first spacing distance da between the first channel structures CHa. For example, the second spacing distance db may be 1.2 to 1.5 times the first spacing distance da, but an example embodiment thereof is not limited thereto.

The second channel structures CHb may have a columnar shape and may include first to third channel portions CH1, CH2, and CH3 penetrating the stack structures GSb, respectively. The first to third channel portions CH1, CH2, and CH3 may have similar shapes, and may have an inclined side surface having a width increasing in a direction away from the planar conductive layer 310 depending on an aspect ratio. The first to third channel portions CH1, CH2, and CH3 may have a bent portion on a boundary. Accordingly, the Z-direction length of the second channel structures CHb may be greater than the Z-direction length of the first channel structures CHa.

The lower end of the third channel portion CH3 of the second channel structures CHb may penetrate the uppermost gate electrode 330U and may protrude downwardly, and may have a channel pad 349 at a lower end, and the channel pad 349 may be connected to the stud 382 in a lower portion and may be connected to bitlines BL1b and BL2b among the cell interconnection lines 384. The upper end of the first channel portion CH1 of the second channel structures CHb may be in direct contact with the planar conductive layer 310 and may electrically connected to each other.

As illustrated in FIG. 5, each of the second channel structures CHb may include a channel layer 340, a channel dielectric layer 345, a channel filling insulating layer 347, and a channel pad 349 disposed in the channel hole, and each component may be substantially the same as those of the first channel structures CHa.

As illustrated in the enlarged diagram in FIG. 4B, the channel layer 340 may have an annular shape surrounding the channel filling insulating layer 347 in an internal portion, but may also have a columnar shape such as a cylindrical shape or a prism shape without the channel filling insulating layer 347 in example embodiments. The channel layer 340 may be connected to the planar conductive layer 310 in an upper portion of the channel hole. The channel layer 340 may include a semiconductor material such as polycrystalline silicon or monocrystalline silicon.

The channel layer 340 may be formed with a predetermined thickness W3 on an x-y plane perpendicular to the Z direction on the side surface of the channel hole, and may extend continuously from an upper end to a lower end of the channel hole. The thickness W3 of the channel layer 340 may be greater than the thickness W1 of the channel layer 140 of the first channel structure CHa, and may be between 6 nm to 11 nm, and may be about 7.5 nm to 8 nm preferably, but an example embodiment thereof is not limited thereto. As described above since the channel layer of the second channel structure CHb has a thickness greater than that of the channel layer 140 of the first channel structure CHa, a deep inversion layer may be formed to store multi-bit, for example, 4-bit data.

The channel dielectric layer 345 may be disposed between the second gate electrodes 330 and the channel layer 340. The channel dielectric layer 345 may be disposed to cover an internal side surface of the channel hole in which the second channel structure CHb is disposed. The channel dielectric layer 345 may include a blocking layer 343, a charge storage layer 342, and a tunneling layer 341 stacked in order from the second gate electrodes 330. The semiconductor device 100 may further include a planar blocking layer, and the planar blocking layer may extend in the planar direction along the second gate electrodes 330. In some example embodiments, the planar blocking layer may not be provided.

The blocking layer 343 and the planar blocking layer may include silicon oxide (SiO₂), silicon nitride (Si₃N₄), silicon oxynitride (SiON), a high-κ material, or a combination thereof. The charge storage layer 342 may be a charge trap layer or a floating gate conductive layer. The tunneling layer 341 may tunnel electric charges into the charge storage layer and may include, for example, silicon oxide (SiO₂), silicon nitride (Si₃N₄), silicon oxynitride (SiON), or a combination thereof.

The blocking layer 343 included in the channel dielectric layer 345 may have a first sub-thickness W41, the charge storage layer 342 may have a second sub-thickness W42, and the tunneling layer 341 may have a third sub-thickness W43, and the first to third sub-thicknesses W41, W42, and W43 may be substantially the same, but an example embodiment thereof is not limited thereto. For example, the first sub-thickness W41 of the blocking layer 343 in an outermost region may be larger than the second and third sub-thicknesses W42 and W43, and may have a greater thickness in a direction away from the channel layer 340, but an example embodiment thereof is not limited thereto. For example, the first sub-thickness W41 may be 1.2 to 1.3 times the third sub-thickness W43, but an example embodiment thereof is not limited thereto. The channel dielectric layer 345 may be formed to have a predetermined thickness W4, which may be larger than the predetermined thickness W3 of the channel layer 340. For example, the thickness W4 of the channel dielectric layer 345 may be larger than the thickness W2 of the channel dielectric layer 145 of the first channel structure CHa. For example, the thickness W4 of the channel dielectric layer 345 may be between 18 nm to 22 nm, and may have a thickness of about 19 nm preferably.

The channel filling insulating layer 347 may be spaced apart from the lower end of the channel hole in the channel layer 340 by a predetermined distance and may fill the channel hole to the upper end of the channel hole. The channel filling insulating layer 347 may include an insulating material, for example, silicon oxide (SiO₂), silicon nitride (Si₃N₄), silicon oxynitride (SiON), or a combination thereof.

A channel pad 349 may be disposed at a lower end of the second channel structure CHb. The channel pad 349 may be connected to the channel layer 340. The channel pad 349 may include a conductive material such as a polycrystalline semiconductor, preferably polysilicon, and may include conductivity-type impurities. For example, when N-type impurities are doped and a common voltage is applied, inversion of the channel layer 340 may be induced depending on a common voltage level.

Referring to FIGS. 3B and 4B, when the lower end of the channel hole has a circular shape, the diameter passing through the center Ob of the circle of the channel hole, that is, the width of the lower end of the second channel structure CHb, may be determined as the second channel width Wb. The second channel width Wb may be larger than the first channel width Wa and smaller than the second spacing distance db. The second channel width Wb may be 130 nm to 400 nm, and for example, 130 nm to 140 nm. The second channel width Wb may be 1.2 to 1.5 times the first channel width Wa, but an example embodiment thereof is not limited thereto.

The second isolation regions MSb may penetrate at least a portion of the second gate electrodes 330 and may extend in the X-direction. As illustrated in FIG. 2, the second isolation regions MSb may be disposed in parallel to each other. The second isolation regions MSb may penetrate the second gate electrodes 330 and may be connected to the second substrate insulating layer 391 therebelow.

The second isolation regions MSb may be the second isolation spacing distance D2 in the Y-direction. The second isolation spacing distance D2 may be greater than the first isolation spacing distance D1, but an example embodiment thereof is not limited thereto. A width of a lower end of the second isolation regions MSb may be equal to or greater than a width of the lower end of the first isolation regions MSa. When the width of the lower end of the second isolation regions MSb is substantially the same as the width of the lower end of the first isolation regions MSa, the first isolation spacing distance D1 and the second isolation spacing distance D2 may be substantially the same, and as the size of the second channel structures CHb is larger in each block BLK, the number of the second channel structures CHb may be smaller than the number of the first channel structures CHa.

However, when the width of the lower end of the second isolation regions MSb is greater than the width of the lower end of the first isolation regions MSa, and the second isolation spacing distance D2 is greater than the first isolation spacing distance D1, the area of each block BLK may be larger than the third structure S3. Accordingly, the number of second channel structures CHb of the third structure S3 in a block BLK may be equal to or greater than the number of first channel structures CHa in a block BLK of the second structure S2.

The second lower insulating regions SSb may extend in the X-direction between the adjacent second isolation regions MSb as illustrated in FIG. 3B. The second lower insulating regions SSb may penetrate at least one upper portion gate electrode 330U among the upper portion gate electrodes 330U between the second channel structures CHb.

The second contact plugs 360 may be connected to the contact regions of the second gate electrodes 330 in the gate pad regions of the second region R2a. The second contact plugs 360 may penetrate at least a portion of the cell region insulating layers 390 and may be connected to the contact regions upwardly exposed, respectively, of the second gate electrodes 330.

The second contact plugs 360 may have a shape corresponding to the second channel structures CHb or a shape corresponding to the isolation region MSb. Each of the second contact plugs 360 may include a bent portion corresponding to a bent portion of the second channel structure and may have an inclined side surface having a width increasing downwardly, and may have a cylindrical shape.

As illustrated in FIG. 2, each of the second contact plugs 360 may have a planarly extended shape in the contact region. The second contact plug 360 may include a vertical extension portion 360V extending in the Z-direction and a planar extension portion 360H extending planarly from the vertical extension portion 360V and in contact with the second gate electrode 330. The planar extension portion 360H may be disposed along the periphery of the vertical extension portion 360V, and the entire side surface may be surrounded by the second gate electrode 330. The length from the side surface of the vertical extension portion 360V to the end of the planar extension portion 360H may be smaller than the length from the side surface of the vertical extension portion 360V to the external side surfaces of the second contact insulating layers 365. The second contact plugs 360 may be spaced apart from the second gate electrodes 330 below the contact regions, that is, the second gate electrodes 330 not electrically connected, by the second contact insulating layers 365.

The second contact insulating layers 365 may be disposed to surround the side surface of each of the second contact plugs 360 below the contact regions. The second contact insulating layers 365 may be spaced apart from each other in the Z-direction at the periphery of each of the second contact plugs 360. The second contact insulating layers 365 may be disposed at substantially the same level as the second gate electrodes 330, respectively.

The support structures SH may be disposed on the peripheral of the second contact plugs 360, and the shape and material thereof may be the same as those of the support structure SH of the second structure S2.

The third structure S3 may further include second through-vias 370 penetrating the second substrate insulating layer 391 in the edge region R3a and connected to the interconnection structures 382 and 384 in a lower portion. The second through-vias 370 may penetrate the second cell region insulating layer 390 and may have a cylindrical shape having a width increasing downwardly, similarly to the second contact plugs 360. The second through-vias 370 may include a common voltage through-via for applying a voltage of a corresponding level to the planar conductive layer 310 and an input/output through-via for applying input/output signals, but an example embodiment thereof is not limited thereto.

The second cell region insulating layer 390 may be disposed to cover the substrate insulating layer 391 and each of the gate pad regions. The second cell region insulating layer 390 may be formed of an insulating material and may include a plurality of insulating layers.

Studs 382 may be included in a second interconnection structure electrically connecting memory cells in the memory cell region. The studs 382 may be electrically connected to second channel structures CHb and second contact plugs 360. The studs 382 may not be disposed on support structures SH. The studs 382 may have a plug form, but an example embodiment thereof is not limited thereto, and the studs 382 may have a line form. In example embodiments, the number of the studs 382 and the number of the cell interconnection lines 384 included in the second interconnection structure may be varied.

Cell interconnection lines 384 may include bitlines BL1b and BL2b of the second region R1b connecting to the second channel structures CHb. The bitlines BL1b and BL2b may have a line shape extending in the Y-direction, and the two second bitlines BL1b and BL2b may extend to the upper surface of the second channel structures CHb. That is, when the two second bitlines BL1b and BL2b are spaced apart from each other on an upper end of the second channel structures CHb, the studs 382 may be alternately in contact with a region between the second bitlines BL1b and BL2b of the second channel structures CHb and one of the second bitlines BL1b and BL2b and may electrically connect the second bitlines BL1b and BL2b of the two second bitlines BL1b and BL2b to one of the second channel structures CHb. A spacing distance between the second bitlines BL1b and BL2b disposed in a row in the X-direction may be the third distance I3. The spacing distance between the second bitlines BL1b and BL2b may be defined as the distance between the centers of the widths of the second bitlines BL1b and BL2b. The third distance I3 between two second bitlines BL1b and BL2b crossing one second channel structure CHb may be the same as or smaller than the fourth distance I4 between two second bitlines BL1b and BL2b crossing the neighboring second channel structure CHb. That is, the spacing distance between the second bitlines BL1b and BL2b may be the third distance I3, or alternatively, the spacing distance between two second bitlines BL1b and BL2b on the second channel structure CHb may be smaller, but an example embodiment thereof is not limited thereto.

Fourth bonding vias 395 of the fourth bonding structure may be disposed in a lower portion of the cell interconnection lines 384 and may be connected to the cell interconnection lines 384, and fourth bonding metal layers 398 of the fourth bonding structure may be connected to the fourth bonding vias 395. The fourth bonding metal layers 398 may have a lower surface exposed to an upper surface of the second structure S2. The fourth bonding metal layers 398 may be bonded and connected to the third bonding metal layers 118 of the second structure S2.

In example embodiments, the substrate insulating layer 391 may include a bonding insulating layer 399 having a predetermined thickness from a lower surface. In this case, the bonding insulating layer 399 may form dielectric-dielectric bonding with the bonding insulating layer 199 of the second structure S2.

The second and third structures S2 and S3 may be bonded to each other by bonding between the third bonding metal layers 118 and the fourth bonding metal layers 398 and bonding between the insulating layers 119 and 399. The bonding between the third bonding metal layers 118 and the second bonding metal layers 398 may be, for example, copper (Cu)-copper (Cu) bonding, and the bonding between the bonding insulating layers 119 and 399 may be, for example, dielectric-dielectric bonding such as SiCN—SiCN bonding. The second and third structures S2 and S3 may be bonded to each other by hybrid bonding including copper (Cu)-copper (Cu) bonding and dielectric-dielectric bonding.

The second channel structures CHb of the third structure S3 may store k-bit data (k=an integer greater than 1) from the second row decoder 22b and the second page buffer 21b in respective memory cells. Accordingly, the second channel structures CHb may function as a multi-level cell. Preferably, the second channel structues CHb may function as a quad level cell (QLC) memory storing 4-bit data in respective memory cells. Accordingly, the third structure S3 may function as a main memory in which pieces of cold data stored for a relatively long period of time are stored, and may store the pieces of cold data with a low response speed, and may read out the stored pieces of cold data.

As described above, the second structure S2 may function as a cache memory or a memory storing hot data requiring frequent access, and may store the allocated hot data with a relatively high response speed, and the third structure S3 may store pieces of cold data stored for a relatively long period of time as a main memory. As described above, by disposing appropriate channel structures according to characteristics of the pieces of data to be stored, and disposing the second structure S2 requiring a relatively high response speed close to the first structure S1, which is a peripheral structure, such that signal transfer may be performed swiftly. Also, memory structures including two different types of memories may be connected and driven by one peripheral structure.

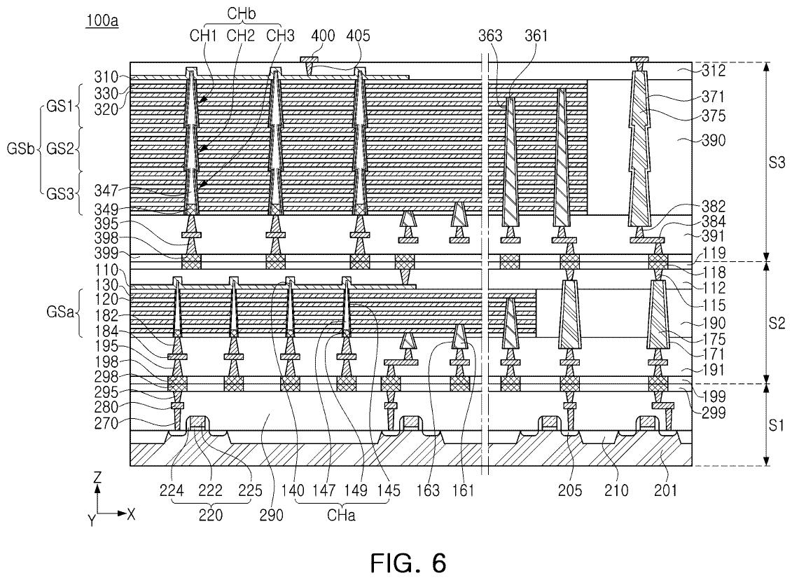

FIGS. 6 to 8 are cross-sectional diagrams illustrating a semiconductor device in example embodiments, corresponding to FIG. 2.

Referring to FIG. 6, a semiconductor device 100a may be the same as the example in FIGS. 1 to 5, other than the shapes of the first contact plugs 161 and the first gate electrodes 130 and the second contact plugs 361 and the second gate electrodes 330. Specifically, the first and second stack structures GSa and GSb may have different numbers of stages, and shapes thereof may be substantially the same. The first and second stack structures GSa and GSb may have a shape not including a step shape and continuously extending from the first region R1a and R1b to the second region R2a and R2b. Accordingly, the gate electrodes 130 and 330 may both have the same area.

The first contact plugs 161 may penetrate at least a portion of the substrate insulating layer 191 and may extend continuously in the Z direction from the upper gate electrode 130U to the assigned gate electrode 130. The first contact plugs 161 may be assigned to different gate electrodes 130 and may extend only to a lower surface of the assigned gate electrode 130, such that an upper surface of the first contact plugs 161 may be electrically and physically connected to a lower surface of the assigned gate electrode 130. Accordingly, the first contact plugs 161 may have different lengths.

The first side insulating layers 163 may be disposed between the first gate electrodes 130 and the first contact plug 161 while covering the side surfaces of the first contact plugs 161, respectively.

The second contact plugs 361 may penetrate at least a portion of the second substrate insulating layer 391 and may extend continuously in the Z direction from the upper gate electrode 330U to the assigned gate electrode 330. The second contact plugs 361 may be assigned to different gate electrodes 330 and may extend only to a lower surface of the assigned gate electrode 330, such that the upper surface of the second contact plugs 361 may be electrically and physically connected to a lower surface of the assigned gate electrode 330. Accordingly, each of the second contact plugs 361 may have a different length.

The second side insulating layers 363 may be disposed between the gate electrodes 330 and the second contact plug 361 while covering each side surface of the second contact plug 361.

In this case, when the gate electrodes 130 and 330 and the interlayer insulating layers 120 and 320 extend to the edge regions R3a and R3b, the through-vias 175 and 375 may extend and penetrate the gate electrodes 130 and 330 and the interlayer insulating layer 120 and 320 without the cell region insulating layer 190 and 390.

The first side insulating layer 171 and the second side insulating layer 371 may be disposed on side surfaces of the through-vias 175 and 375 and may insulate between the gate electrodes 130 and 330 and the through-vias 175 and 375.

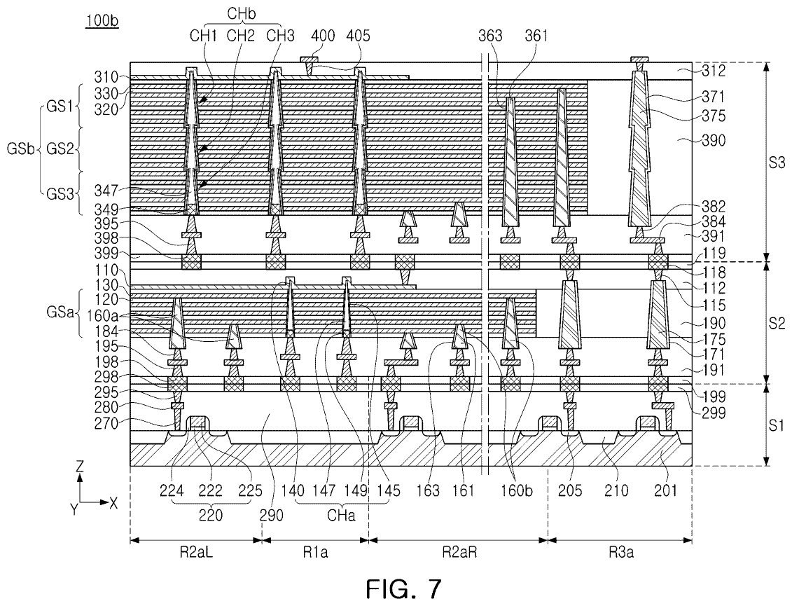

Referring to FIG. 7, a semiconductor device 100b may be the same as the semiconductor device 100a in FIG. 6 other than the shape of the second structure S2.

The semiconductor device 100b may include a left-side second region R2aL and a right-side second region R2aR on both sides of the first region R1a in the second structure S2.

The right-side second region R2aR may be disposed between the first region R1a and the third region R3a and may have the same shape as that of the second region R2a in FIG. 6.

The semiconductor device 100b in FIG. 7 may further include a left-side second region R2aL on the left side of the first region R1a.

In the left-side second region R2aL, the stack structure GSa may extend to the left-side second region R2aL and the first contact plugs 160a may be disposed.

The number of the first contact plugs 160a and 160b of the left-side second region R2aL and the right-side second region R2aR may be the same. The same gate electrode 130 may be assigned to the first contact plugs 160a of the left-side second region R2aL and the first contact plugs 160b of the right-side second region R2aR. That is, one first contact plug 160a of the left-side second region R2aL and one first contact plug 160b of the right-side second region R2aR may be simultaneously connected to the same gate electrode 130.

As described above, when the same word signal is applied to the same gate electrode 130 on both sides of the first region R1a, signal resistance may decrease and a signal may be transmitted and received at a faster response speed.

In this case, in the third structure S3, the second region R2b may be disposed only on one side of the first region R1b, such that the first region R1b of the third structure S3 may overlap the left-side second region R2aL of the second structure S2 in the Z-direction, but an example embodiment thereof is not limited thereto.

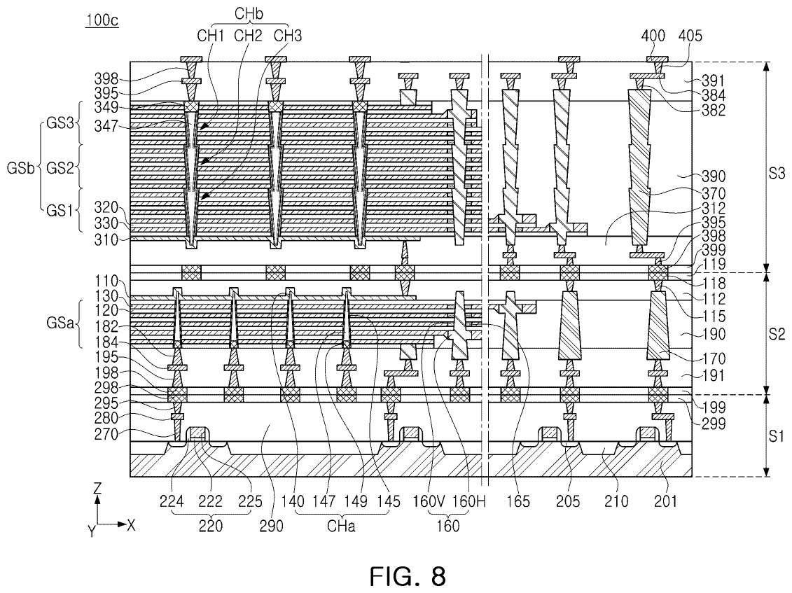

Referring to FIG. 8, a semiconductor device 100c may be the same as the semiconductor device 100 in FIG. 2 other than the arrangement of the third structure S3.

The semiconductor device 100c in FIG. 8 may have the second stack structures GSb disposed on the second planar conductive layer 310, and the second channel structures CHb penetrating the second stack structure GSb may have a shape of which a width decreases toward the second planar conductive layer 310 from the channel portions CH1, CH2, and CH3, respectively.

The slope direction of the second channel structures CHb may be opposite to the slope direction of the first channel structures CHa. The slope direction of the second contact plugs 360 may also be opposite to the slope direction of the first contact plugs 160, and the slope direction of the second through-vias 370 may also be opposite to the slope direction of the first through-vias 170.

As described above, when the third structure S3 is bonded to the second structure S2 in an opposite manner, the third structure S3 may include the interconnection structures 400 and 405 in a lower portion of the second planar conductive layer 310, and the fourth bonding structures 395 and 398 connected to the interconnection structures 400 and 405 may be electrically and physically connected to the third bonding structures 115 and 118.

In this case, when the third structure S3 and the second structure S2 are bonded to each other in the opposite directions, the first planar conductive layer 110 and the second planar conductive layer 310 may be disposed close to the third bonding structures 115, 118 and the fourth bonding structures 395 and 398. Accordingly, the first planar conductive layer 110 and the second planar conductive layer 310 may be simultaneously applied with a common source voltage.

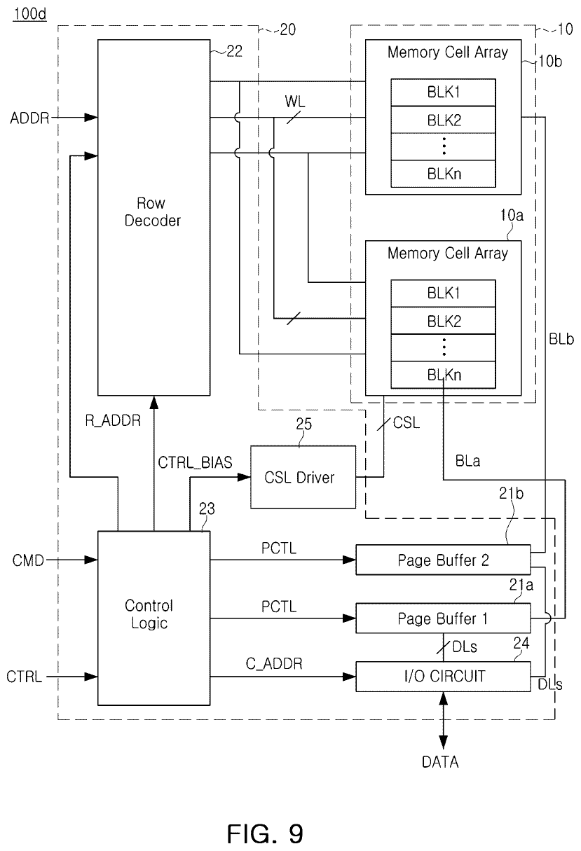

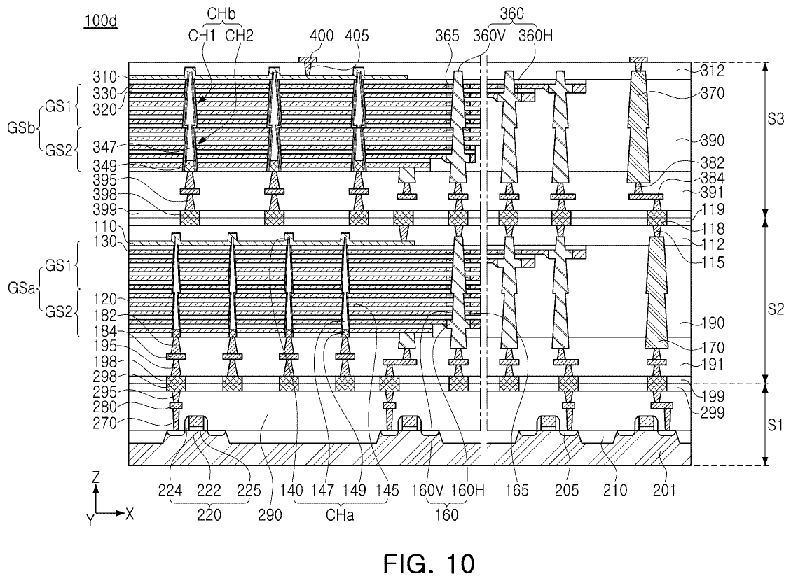

Hereinafter, with reference to FIGS. 9 and 10, a semiconductor device according to an exemplary embodiment may be described.

FIG. 9 is a diagram illustrating a data storage system including a semiconductor device according to example embodiments. FIG. 10 is a cross-sectional diagram illustrating the semiconductor device illustrated in FIG. 9.

Referring to FIG. 9, a semiconductor device 100d according to one example embodiment may include a first memory cell array 10a and a second memory cell array 10b of different types. The peripheral circuit region may include a row decoder 22 simultaneously applying a word line signal to the first memory cell array 10a and the second memory cell array 10b.

That is, the first memory cell array 10a and the second memory cell array 10b may be connected to the first page buffer 21a and the second page buffer 21b, respectively as illustrated in FIG. 1, and may transmit signals from the bitlines BLa and BLb, respectively, and may simultaneously operate by receiving a word line signal WL from one row decoder 22.

Accordingly, when one first contact plug 160 is selected in the first memory cell array 10a, one second contact plug 360 may be selected in the second memory cell array 10b, such that the memory cells of the corresponding level may be activated simultaneously.

To this end, the semiconductor device 100d may include a second structure S2 corresponding to the first memory cell array 10a and a third structure S3 corresponding to the second memory cell array 10b as illustrated in FIG. 10, and the number of gate electrodes 130 of the second structure S2 and the number of third gate electrodes 330 of the third structure S3 may be the same.

Accordingly, when the first stack structure GSa of the second structure S2 may include j number of stages, the second stack structure GSb of the third structure S3 may also include the same j number of stages.

In FIG. 10, the second and third structures S2 and S3 may include the same two stages of stack structures GSa and GSb, but an example embodiment thereof is not limited thereto.

Accordingly, when the second channel structure CHb includes a bent portion, the first channel structure CHa also may include a bent portion, and the numbers of channel portions CH1 and CH2 may be the same.

Similarly, the second and third structures S2 and S3 having the same number of gate electrodes 130 and 330 may include the same number of first and second contact plugs 160 and 360 connected to the gate electrodes 130 and 330, respectively.

The first and second contact plugs 160 and 360 may be electrically connected by the third and fourth bonding interconnections 118 and 398, and may be connected to circuit devices included in the row decoder 22 of the first structure S1 and may receive word signals simultaneously.

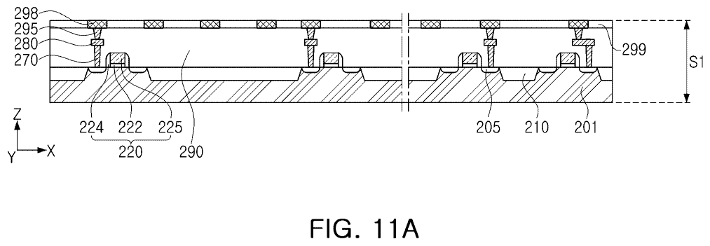

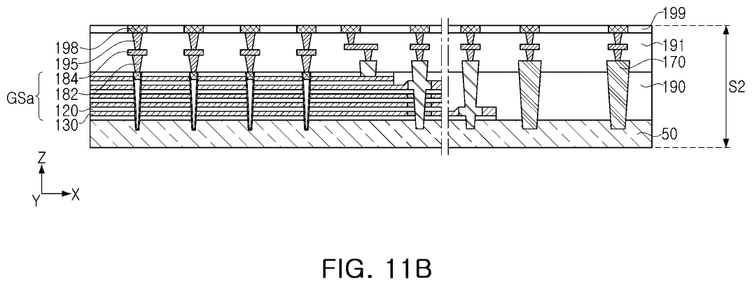

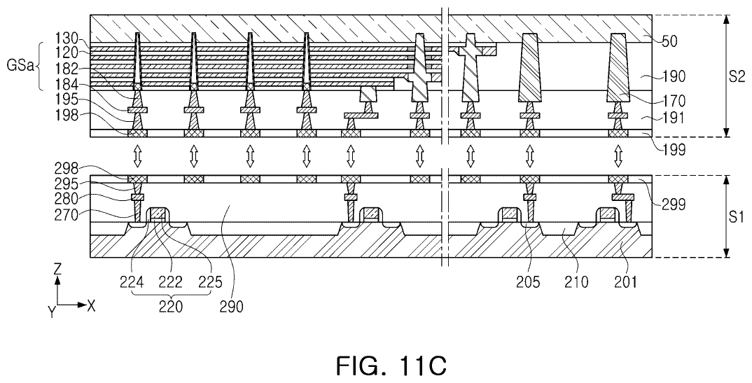

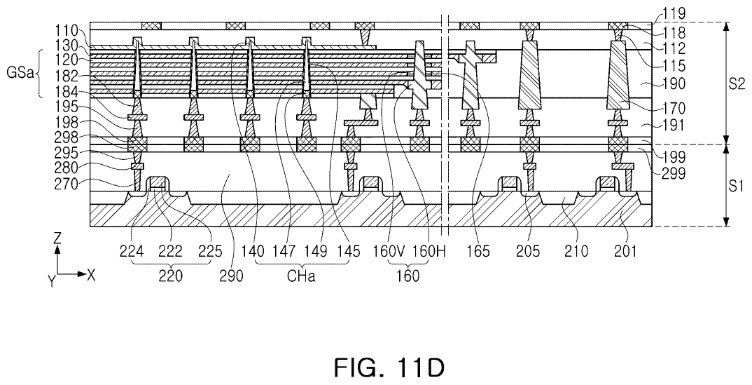

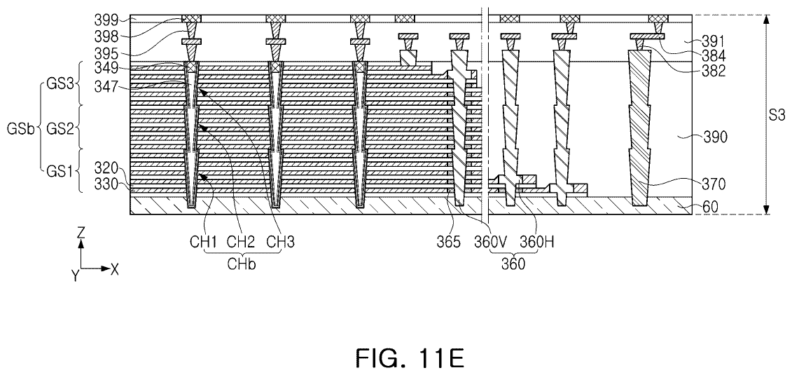

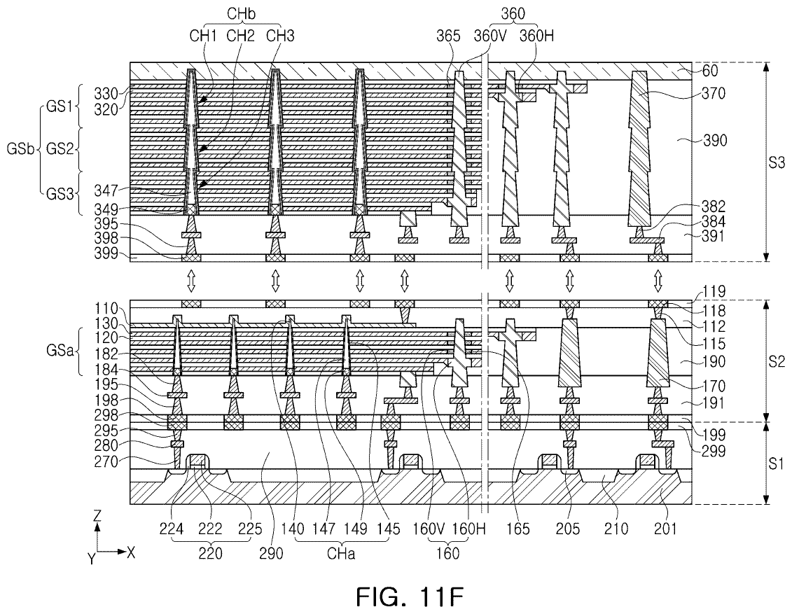

FIGS. 11A to 11F are cross-sectional diagrams illustrating a method of manufacturing a semiconductor device according to example embodiments.

Referring to FIG. 11A, a first structure PERI including circuit devices 220 and circuit interconnection structures may be formed on a first substrate 201.

First, device isolation layers 210 may be formed in the first substrate 201, and a circuit channel dielectric layer 222 and a circuit gate electrode 225 may be formed in order on the first substrate 201. The device isolation layers 210 may be formed, for example, by a shallow trench isolation (STI) process. The circuit channel dielectric layer 222 and the circuit gate electrode 225 may be formed using atomic layer deposition (ALD) or chemical vapor deposition (CVD). The circuit channel dielectric layer 222 may be formed of silicon oxide, and the circuit gate electrode 225 may be formed of at least one of polycrystalline silicon or a metal silicide layer, but an example embodiment thereof is not limited thereto. Thereafter, a spacer layer 224 and source/drain regions 205 may be formed on both sidewalls of the circuit channel dielectric layer 222 and the circuit gate electrode 225. In example embodiments, the spacer layer 224 may include a plurality of layers. Thereafter, an ion implantation process may be performed and the source/drain regions 205 may be formed.

Among the circuit interconnection structures, the circuit contact plugs 270 may be formed by partially forming a peripheral region insulating layer 290, removing by etching a portion, and filling a conductive material. The circuit interconnection lines 280 may be formed, for example, by depositing a conductive material and performing patterning.

The peripheral region insulating layer 290 may include a plurality of insulating layers. The peripheral region insulating layer 290 may be formed by forming a portion in each of operations forming the circuit interconnection structures and forming a portion in an upper portion of the circuit interconnection line 280 of the uppermost portion, thereby covering the circuit devices 220 and the circuit interconnection structures.

Referring to FIG. 11B, a second structure S2 may be formed on the first sacrificial substrate 50.

The forming the second structure S2 may include forming gate electrodes 130, a first channel structure CHa penetrating the gate electrodes 130, and cell interconnections electrically connected thereto on the first sacrificial substrate 50, forming a cell region insulating layer 190 covering the gate electrodes 130, the channel structures CHa, and the cell interconnections, and forming second bonding structures 195 and 198 on the cell interconnections.

In this case, the second structure S2 may be formed such that the stack structure GSa may form one stage, and the first channel structure CHa and the first contact plugs 160 may have continuous slopes without a bent portion.

Referring to FIG. 11C, after forming the second structure S2, the second structure S2 may be inverted such that the second bonding insulating layer 199 of the second structure S2 may face the first bonding insulating layer 299 of the first structure S1, and may be disposed on the first structure S1. Accordingly, the first structure S1 and the second structure S2 may be physically and electrically connected to each other by hybrid bonding between the second bonding structures 198 and 199 and the first bonding structures 298 and 299.

Referring to FIG. 11D, the first sacrificial substrate 50 exposed to an upper portion of the second structure S2 may be removed, and the channel dielectric layer 145 may be removed from a lower end of the first channel structures CHa and the channel layer 140 may be exposed. While the channel layer 140 of the first channel structures CHa is exposed, the planar conductive layer 110 may be stacked.

The planar conductive layer 110 may be formed by depositing conductive materials, but an example embodiment thereof is not limited thereto. The planar conductive layer 110 may be formed conformally according to the shape of the channel layer 140 of the first channel structure CHa and may be bent, or the upper surface may also be formed flat to cover the entire channel layer 140.

A cover insulating layer 112 may be formed on the first planar conductive layer 110, and upper interconnections and third bonding structures 115 and 118 may be formed.

Referring to FIG. 11E, a third structure S3 may be formed on the second sacrificial substrate 60.

The forming the third structure S3 may be similar to the forming the second structure S2, and in the case of including a stack structure GSb having a plurality of stages, the first molding structure corresponding to the stack structure GS1 of one stage and the vertical sacrificial structures corresponding to the first channel portion CH1 of the second channel structure CHb may be formed, and the vertical sacrificial structures corresponding to the second molding structure and the second channel portion CH2 of the stack structure GS2 of two stages may be formed, thereby forming the mold structure and vertical sacrificial structures of multiple stages.

The first mold structure may be formed on the second sacrificial substrate 60 at a level at which the first gate structure GS1 (see FIG. 2) is disposed. The sacrificial insulating layers may be layers in which at least a portion is replaced with a portion of the second gate electrodes 330 (see FIG. 2) through a subsequent process. The sacrificial insulating layers may be formed of a material different from that of the second interlayer insulating layers 320 and may be formed of a material etched with etch selectivity under specific etch conditions with respect to the second interlayer insulating layers 320. By repeatedly performing a photolithography process and an etching process for the sacrificial insulating layers and the second interlayer insulating layers 320, a gate pad region may be formed.

The vertical sacrificial structures may be formed in a region corresponding to the second channel structures CHb in FIG. 2. The vertical sacrificial structures may include a material different from that of the second interlayer insulating layers 320 and the sacrificial insulating layers. For example, the vertical sacrificial structures may include a semiconductor material such as polycrystalline silicon, a silicon-based insulating material, or a carbon-based material.

The vertical sacrificial structures may be removed from a plurality of mold structures, and second channel structures CHb may be formed. The second channel structures CHb may be formed to have a diameter larger than a diameter of the first channel structures CHa, and the channel dielectric layer 345 may have a larger thickness, and the channel layer 340 may have a larger thickness.

The channel dielectric layers 345 may be formed by depositing a blocking layer 341, a charge storage layer 342, and a tunneling layer 343 in order in the channel holes. The channel dielectric layers 345 may be formed to have a uniform thickness using an atomic layer deposition (ALD) or chemical vapor deposition (CVD) process.

The channel layer 340 may be formed on the channel dielectric layer 345 in the channel holes. A channel filling insulating layer 347 may be formed to fill the channel holes, and a channel pad 349 may be formed on an upper portion thereof. Thereafter, second contact plugs 360 may be formed using a conductive material, and second through-vias 370 may be formed using a conductive material.

Thereafter, openings penetrating the mold structures may be formed, sacrificial insulating layers may be removed, and a substitution process of filling the conductive material, thereby forming second gate electrodes 330, and forming second isolation regions MSb.

The conductive material included in the second gate electrodes 330 may fill the tunnel portions. The conductive material may include a metal, polycrystalline silicon, or a metal silicide material.

Second circuit structures 382 and 384 may be formed on the second channel structure CHb, the second contact plugs 360 and the second through-vias 370, and fourth bonding structures 395 and 398 may be formed on an upper portion thereof.

Thereafter, as illustrated in FIG. 11F, after forming the third structure S3, the third structure S3 may be inverted such that the fourth bonding insulating layer 399 of the third structure S3 may face the third bonding insulating layer 119 of the second structure S2, and may be disposed on the second structure S2. Accordingly, the second structure S2 and the third structure S3 may be physically and electrically connected to each other by hybrid bonding between the fourth bonding structure 395 and 399 and the third bonding structure 115 and 119.

The second sacrificial substrate 60 exposed to the upper portion of the third structure S3 may be removed, the channel dielectric layer 345 may be removed from the lower end of the second channel structures CHb and the channel layer 340 may be exposed. In a state in which the channel layer 340 of the second channel structures CHb is exposed, the second planar conductive layer 310 may be formed.

The second planar conductive layer 310 may be formed by depositing conductive materials, but an example embodiment thereof is not limited thereto. The second planar conductive layer 310 may be formed conformally according to the shape of the channel layer 340 of the channel structure CHb and may be bent, but the upper surface may also be formed flat so as to cover the entire channel layer 340.

By forming a cover insulating layer 312 on the second planar conductive layer 310 and further forming interconnection structures 400 and 405, the semiconductor device 100 in FIG. 2 may be manufactured.

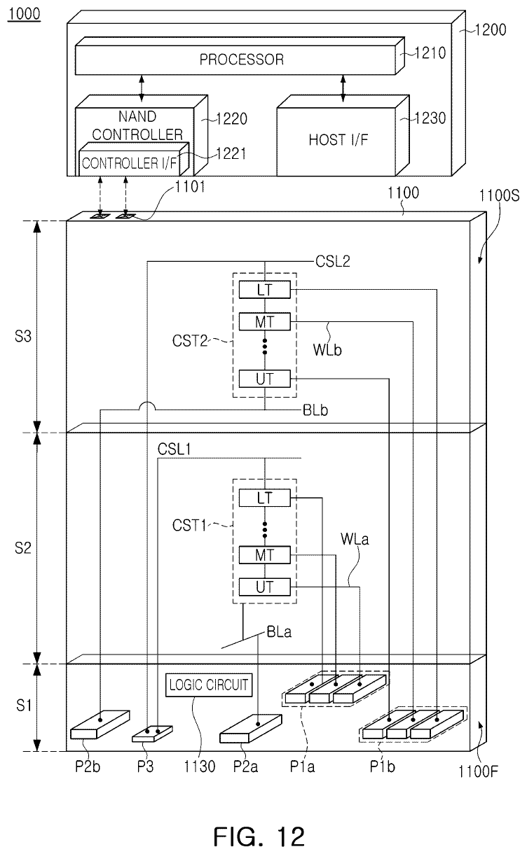

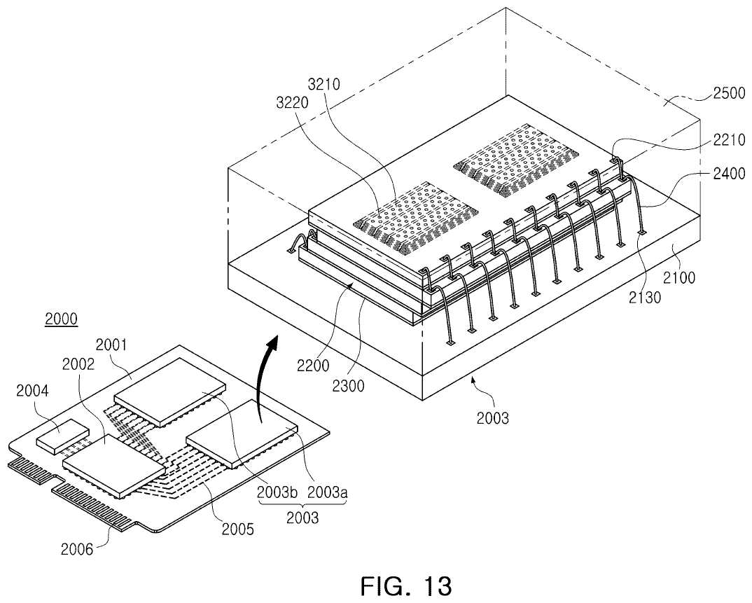

FIG. 12 is a diagram illustrating a semiconductor device according to example embodiments.

Referring to FIG. 12, a data storage system 1000 may include a semiconductor device 1100 and a controller 1200 electrically connected to the semiconductor device 1100. The data storage system 1000 may be implemented as a storage device including one or more semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device described in the aforementioned example embodiment with reference to FIGS. 1 to 10. The semiconductor device 1100 may include a first structure 1100F and a second structure 1100S on the first structure 1100F. In the example embodiments, the first structure 1100F may be disposed on the side of the second structure 1100S. The first structure 1100F may be configured as a peripheral circuit structure including a first decoder circuit P1a, a second decoder circuit P1b, a first page buffer P2a, a second page buffer P2b and a logic circuit 1130. The second structure 1100S may have a structure in which the second structure S2 and the third structure S3 are stacked, and may be a memory cell structure including a first bitline BLa, a second bitline BLb, first and second common source lines CSLa and CSLb, first and second wordlines WLa and WLb, first and second gate upper lines UL1 and UL2, first and second gate lower lines LL1 and LL2, and first and second memory cell strings CST1, CST2 between the first and second bitlines BLa and BLb and the first and second common source lines CSLa and CSLb.

In the second structure 1100S, each of the first memory cell strings CST1 may include lower transistors LT adjacent to the first common source line CSLa, upper transistors UT adjacent to the first bitline BLa, and a plurality of memory cell transistors MT disposed between the upper transistors UT and the lower transistors LT.

In example embodiments, the lower transistors LT may include ground select transistors, and the upper transistors UT may include string select transistors. Each of the gate lower lines may be a gate electrode of the lower transistors LT. Each of the first wordlines WL may be a gate electrode of the memory cell transistors MCT, and each of the gate upper lines may be a gate electrode of the upper transistors UT.

In example embodiments, the lower transistors LT may include a lower erase control transistor and a ground select transistor connected to each other in series. The upper transistors UT may be string select transistors connected to each other in series.

The first common source line CSL1, the first and second gate lower lines, the wordlines WLa, and the first and second gate upper lines may be electrically connected to the first decoder circuit P1a through first interconnections extending from the first structure 1100F to the second structure S2. The first bitlines BLa may be electrically connected to the first page buffer P2a through second interconnections extending from the first structure 1100F to the second structure S2.

Each of the second memory cell strings CST2 may include lower transistors LT adjacent to the second common source line CSL2, upper transistors UT adjacent to the second bitline BLb, and a plurality of memory cell transistors MT disposed between the lower transistors LT and the upper transistors UT.

In example embodiments, the lower transistors LT may include a ground select transistor, and the upper transistors UT may include a string select transistor. The gate lower lines may be gate electrodes of the lower transistors LT, respectively. The second wordlines WLb may be gate electrodes of the memory cell transistors MCT, and the gate upper lines may be gate electrodes of the upper transistors UT, respectively.

In example embodiments, the lower transistors LT may include lower erase control transistors and ground select transistors connected to each other in series. The upper transistors UT may be string select transistors connected to each other in series.

The common source line CSL2, the second and second gate lower lines, the second wordlines WLb, and the second gate upper lines may be electrically connected to the second decoder circuit P1b through second interconnections extending to the second structure S2 in the second structure 1100F. The second bitlines BLb may be electrically connected to the second page buffer P2b through second interconnections extending to the second structure S2 in the second structure 1100F.

The first memory cell transistors MT1 may store 1 bit of data, and the second memory cell transistors MT2 may store more bits of data, for example, 4 bits of data.

In the first structure S1, the first and second decoder circuits P1a and P1b and the first and second page buffers P2a and P2b may execute a control operation for at least one select memory cell transistor among the plurality of memory cell transistors MT. The first and second decoder circuits P1a and P1b and the first and second page buffers P2a and P2b may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through input/output interconnection extending from the first structure S1 to the third structure S3.

The controller 1200 may include a processor 1210, a NAND controller 1220, and a host interface 1230. In example embodiments, the data storage system 1000 may include a plurality of semiconductor devices 1100, and in this case, the controller 1200 may control a plurality of semiconductor devices 1100.

The processor 1210 may control operations of the data storage system 1000, including the controller 1200. The processor 1210 may be operated according to predetermined firmware and may control the NAND controller 1220 to access the semiconductor devices 1100. The NAND controller 1220 may include a controller interface 1221 that handles communication with the semiconductor device 1100. Through the controller interface 1221, control commands for controlling the semiconductor device 1100, data to be written to memory cell transistors MCT of the semiconductor device 1100, data to be read from memory cell transistors MCT of the semiconductor device 1100, or the like, may be transmitted. The host interface 1230 may provide a communication function between the data storage system 1000 and an external host. When a control command is received from an external host through the host interface 1230, the processor 1210 may control the semiconductor device 1100 in response to the control command.

FIG. 13 is a perspective diagram illustrating a data storage system including a semiconductor device according to an example embodiment.

Referring to FIG. 13, a data storage system 2000 in an example embodiment may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may vary depending on a communication interface between the data storage system 2000 and the external host. In the example embodiments, the data storage system 2000 may communicate with an external host according to one of interfaces from among universal serial bus (USB), peripheral component interconnect express (PCI-Express), serial advanced technology attachment (SATA), M-Phy for universal flash storage (UFS). In the example embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be configured as a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of the semiconductor chips 2200, respectively, a bonding structure 2400 electrically connecting the semiconductor chips 2200 to the package substrate 2100, and a molding layer 2500 covering the semiconductor chips 2200 and the bonding structure 2400 on the package substrate 2100.

The package substrate 2100 may be configured as a printed circuit board including package upper pads 2130. Each semiconductor chip 2200 may include an input/output pad 2210. The input/output pad 2210 may correspond to the input/output pad 1101 in FIG. 13. Each of the semiconductor chips 2200 may include gate stack structures 3210 and channel structures 3220. Each of the semiconductor chips 2200 may include the semiconductor device described in the aforementioned example embodiment with reference to FIGS. 1 to 10.

In the example embodiments, the bonding structure 2400 may be configured as a bonding wire electrically connecting the input/output pad 2210 to the upper package pads 2130. Accordingly, in each of the first and second semiconductor packages 2003a and 2003b, the semiconductor chips 2200 may be electrically connected to each other by a bonding wire method, and may be electrically connected to the upper pads 2130 of the package substrate 2100. In the example embodiments, in each of the first and second semiconductor packages 2003a and 2003b, the semiconductor chips 2200 may be electrically connected to each other by a connection structure including a through-electrode (TSV) instead of the bonding structure 2400 of a bonding wire method.

In the example embodiments, the controller 2002 and the semiconductor chips 2200 may be included in a single package. In an example embodiment, the controller 2002 and the semiconductor chips 2200 may be mounted on an interposer substrate different from the main board 2001, and the controller 2002 and the semiconductor chips 2200 may be connected to each other by interconnection formed on the interposer substrate.

According to the aforementioned example embodiments, by forming different channel structures in two cell structures connected to the peripheral structure, hot data may be stored in the first cell structure and cold data may be stored in the second cell structure according to characteristics of the data being stored. To this end, the second cell structure may form a channel structure including QLC and may provide an optimal storage system according to characteristics of the data.

Accordingly, a semiconductor device having improved reliability and integration density and a data storage system including the same may be provided.

While the example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a first memory structure including (i) a first stack structure including first gate electrodes stacked and spaced apart from each other in a vertical direction, (ii) first channel structures penetrating the first stack structure in the vertical direction, (iii) first circuit interconnections connected to the first channel structures, and (iv) a first bonding structure connected to the first circuit interconnections;
a second memory structure disposed on the first memory structure, and including (i) second stack structures including second gate electrodes stacked and spaced apart from each other in the vertical direction, (ii) second channel structures penetrating the second stack structures in the vertical direction, (iii) second circuit interconnections connected to the second channel structures, and (iv) a second bonding structure connected to the second circuit interconnections and bonded to the first bonding structure; and
a peripheral circuit structure disposed adjacent to a lower portion of the first memory structure and electrically connected to the first memory structure by a third bonding structure,
wherein the number of bits stored in each of memory cells of the first channel structures is different from the number of bits stored in each of the memory cells of the second channel structures.

2. The semiconductor device of claim 1, wherein each of the memory cells of the first channel structures stores a single-bit data, and each of the memory cells of the second channel structures stores multi-bit data.

3. The semiconductor device of claim 1,
wherein each of the first channel structures includes an inclined side surface between an upper end and a lower end, and
wherein each of the second channel structures includes channel portions penetrating the second stack structures, respectively, and includes a bent portion between the channel portions.

4. The semiconductor device of claim 3,
wherein a width of the upper end of each of the first channel structures is less than a width of the lower end of each of the first channel structures,
wherein a width of an upper end of each of the second channel structures is less than a width of a lower end of each of the second channel structures, and
wherein the width of the lower end of each of the first channel structures is less than the width of the lower end of each of the second channel structures.

5. The semiconductor device of claim 4, wherein the width of the lower end of each of the second channel structures is between 1.2 and 1.5 times the width of the lower end of each of the first channel structures.

6. The semiconductor device of claim 1,
wherein each of the first channel structures includes a first channel layer and a first channel dielectric layer between the first channel layer and the first gate electrodes, and
wherein each of the second channel structures includes a second channel layer and a second channel dielectric layer between the second channel layer and the second gate electrodes.

7. The semiconductor device of claim 6, wherein a thickness of the second channel layer is greater than a thickness of the first channel layer.

8. The semiconductor device of claim 6, wherein a thickness of the second channel dielectric layer is greater than a thickness of the first channel dielectric layer.

9. The semiconductor device of claim 1, wherein the number of the second gate electrodes is greater than the number of the first gate electrodes.

10. The semiconductor device of claim 1, wherein a length in the vertical direction of each of the second channel structures is greater than a length in the vertical direction of each of the first channel structures.

11. The semiconductor device of claim 1,
wherein the first circuit interconnections include two first bitlines spaced apart from each other on a lower end of each of the first channel structures,
wherein the second circuit interconnections include two second bitlines spaced apart from each other on a lower end of each of the second channel structures, and
wherein a first spacing distance between two first bitlines disposed on the lower end of each of the first channel structures is less than a second spacing distance between two second bitlines disposed on the lower end of each of the second channel structures.

12. The semiconductor device of claim 1,
wherein the first channel structures are arranged and spaced apart from each other by a first distance,
wherein the second channel structures are arranged and spaced apart from each other by a second distance, and
wherein the first distance is less than the second distance.

13. The semiconductor device of claim 1,
wherein the first memory structure includes a 1-1 region in which the first channel structures are disposed, and a 1-2 region in which first contact plugs connected to the first gate electrodes, respectively, are disposed, wherein the 1-2 region is disposed on one side of the 1-1 region,
wherein the second memory structure includes a 2-1 region in which the second channel structures are disposed, and a 2-2 region in which second contact plugs connected to the second gate electrodes, respectively, are disposed, wherein the 2-2 region is disposed on one side of the 2-1 region, and
wherein the number of the first contact plugs is less than the number of the second contact plugs.

14. The semiconductor device of claim 13, wherein the first memory structure further includes a 1-3 region in which third contact plugs connected to the first gate electrodes, respectively, are disposed, wherein the 1-3 region is disposed on the other side of the 1 -1 region.

15. The semiconductor device of claim 14, wherein one of the first contact plugs and one of the third contact plugs are connected together to one of the first gate electrodes.

16. A semiconductor device, comprising:
a peripheral circuit structure including a first page buffer and a second page buffer, a first row decoder and a second row decoder, and a logic controller selectively operating the first page buffer and the first row decoder or the second page buffer and the second row decoder depending on characteristics of data to be stored;
a first memory structure disposed on the peripheral circuit structure, and including (i) a first stack structure including first gate electrodes stacked and spaced apart from each other in a vertical direction and each receiving a first word signal from the first row decoder, (ii) first channel structures penetrating the first stack structure in the vertical direction, and (iii) first bitlines connected to the first channel structures and receiving first bit signals from the first page buffer; and
a second memory structure disposed on the first memory structure, and including (i) second stack structures including second gate electrodes stacked and spaced apart from each other in the vertical direction and each receiving a second word signal from the second row decoder, (ii) second channel structures penetrating the second stack structures in the vertical direction, and (iii) second bitlines connected to the second channel structures and receiving second bit signals from the second page buffer,
wherein the first channel structures store hot data, and the second channel structures store cold data.

17. The semiconductor device of claim 16, wherein memory cells of each of the first channel structures stores a single-bit data, and memory cells of each of the second channel structures stores multi-bit data.

18. The semiconductor device of claim 16, wherein the second channel structures include quad level cells (QLC).

19. A data storage system, comprising:
a main substrate;
a semiconductor device on the main substrate; and
a controller electrically connected to the semiconductor device on the main substrate,
wherein the semiconductor device includes:
a first memory structure including (i) a first stack structure including first gate electrodes stacked and spaced apart from each other in the vertical direction, (ii) first channel structures penetrating the first stack structure in the vertical direction, (iii) first circuit interconnections connected to the first channel structures, and (iv) a first bonding structure connected to the first circuit interconnections;
a second memory structure disposed on the first memory structure, and including (i) second stack structures including second gate electrodes stacked and spaced apart from each other in the vertical direction, (ii) second channel structures penetrating the second stack structures in the vertical direction, (iii) second circuit interconnections connected to the second channel structures, and (iv) a second bonding structure connected to the second circuit interconnections and bonded to the first bonding structure; and
a peripheral circuit structure disposed adjacent to a lower portion of the first memory structure and electrically connected to the first memory structure by a third bonding structure,
wherein the number of bits stored in each of memory cells of the first channel structures is different from the number of bits stored in each of the memory cells of the second channel structures.

20. The data storage system of claim 19,
wherein each of the first channel structures includes a single level cell (SLC), and
wherein each of the second channel structures includes a quad level cell (QLC).
